(19) United States
(12) Patent Application Publication
(10) Pub. No.: US 2026/0032832 A1
(43) Pub. Date: Jan. 29, 2026

(54) ELECTRONIC DEVICE INCLUDING FLEXIBLE DISPLAY

(71) Applicant: Samsung Electronics Co., Ltd., Suwon-si (KR)

(72) Inventors: Sungho AHN, Suwon-si (KR); Dohyung KIM, Suwon-si (KR); Woosub KIM, Suwon-si (KR); Jihyung JUNG, Suwon-si (KR); Soyoung LEE, Suwon-si (KR)

(21) Appl. No.: 19/288,469

(22) Filed: Aug. 1, 2025

Related U.S. Application Data
(63) Continuation of application No. PCT/KR2025/010498, filed on Jul. 16, 2025.

(30) Foreign Application Priority Data
Jul. 24, 2024 (KR) 10-2024-0097973
Sep. 20, 2024 (KR) 10-2024-0127511

(51) Int. Cl. H05K 5/02

(52) U.S. Cl. CPC H05K 5/02

(57) ABSTRACT

An electronic device is provided. The electronic device includes a first housing, a second housing configured to move with respect to the first housing, and a flexible display including a first display portion and a second display portion, wherein at least part of the second portion is drawn into or withdrawn from an internal space of the electronic device in accordance with the second housing moving with respect to the first housing, wherein the flexible display includes a first window layer, a second window layer disposed on the first window layer, and at least two adhesive layers including a first adhesive layer and a second adhesive layer, disposed between the first window layer and the second window layer, the at least two adhesive layers configured to adhesively attach the first window layer to the second window layer, wherein the first adhesive layer includes a first adhesive portion corresponding to the first display portion and a second adhesive portion corresponding to the second display portion, wherein a modulus of the second adhesive portion is lower than a modulus of the first adhesive portion, and a modulus of the second adhesive layer is equal to or lower than the modulus of the first adhesive portion.

### CROSS-REFERENCE TO RELATED APPLICATION(S)

This application is a continuation application, claiming priority under 35 U.S.C. § 365 (c), of an International application No. PCT/KR2025/010498, filed on Jul. 16, 2025, which is based on and claims the benefit of a Korean patent application number 10-2024-0097973, filed on Jul. 24, 2024, in the Korean Intellectual Property Office, and of a Korean patent application number 10-2024-0127511, filed on Sep. 20, 2024, in the Korean Intellectual Property Office, the disclosure of each of which is incorporated by reference herein in its entirety.

### TECHNICAL FIELD

The disclosure relates to an electronic device including a flexible display.

### BACKGROUND ART

Electronic devices are gradually becoming slimmer and more rigid, being enhanced in design aspects, and being improved to differentiate functional elements thereof. Electronic devices are gradually evolving from a uniform rectangular shape to diverse shapes. An electronic device may have a transformable structure that is convenient to carry and enables the use of a large-screen display. The electronic device may include a rollable electronic device (e.g., a slidable electronic device) capable of varying the display area of a flexible display (e.g., a rollable display) through the support of housings that operate in a sliding manner relative to each other.

The above information is presented as background information only to assist with an understanding of the disclosure. No determination has been made, and no assertion is made, as to whether any of the above might be applicable as prior art with regard to the disclosure.

### DISCLOSURE OF INVENTION

### Technical Problem

An electronic device may include a rollable electronic device (e.g., a slidable electronic device) in which the display area of a flexible display is expandable and/or contractible. The rollable electronic device may include a first housing (e.g., a first housing structure, a moving structure, a slide housing, a slide bracket, or a slide structure) and a second housing (e.g., a second housing structure, a fixed structure, a base housing, a base bracket, or a base structure) that are at least partially fitted together and coupled to each other in a slidable manner. For example, the first housing and the second housing are slidably operated relative to each other and support at least a portion of a flexible display (e.g., an expandable display or a stretchable display) so as to guide the flexible display to have a first display area in a slide-in state and a second display area greater than the first display area in a slide-out state.

The flexible display may include a display panel and a plurality of layers laminated above and/or below the display panel via an adhesive member (e.g., pressure-sensitive adhesive (PSA)). For example, the plurality of layers may include a first window layer (a first layer, a first window layer, or a glass layer), a second window layer (a second layer or a protective layer), or a plurality of functional layers.

Meanwhile, the flexible display may include a first portion (e.g., a planar portion) that is always visible from the outside and a second portion (e.g., a curved portion or a bending portion) extending from the first portion and at least partially accommodated in an inner space of the electronic device in a bending manner in the slide-in state. An adhesive layer including a plurality of adhesive members having different moduli may be disposed between the first window layer and the second window layer. The adhesive layer may include a first adhesive portion corresponding at least partially to the first portion and a second adhesive portion corresponding at least partially to the second portion when viewed from above the flexible display. The first adhesive portion may be made of a relatively rigid material compared to the second adhesive portion so as to increase the rigidity of the first portion, which is always visible from the outside of the electronic device. The second adhesive portion may be made of a softer material compared to the first adhesive portion so as to accommodate slip occurring between the plurality of layers (e.g., the first window layer, the second window layer, and/or the functional layers) constituting the flexible display during the slide-in or slide-out operation of the electronic device.

When the first adhesive portion having a high modulus is used to enhance the durability of the flexible display, the fluidity of the first adhesive portion may decrease during the sliding operation of the electronic device. In this case, as the intensity of stress applied to the second adhesive portion increases, the strain of the second adhesive portion may increase, thereby increasing the likelihood of fatigue failure.

Conversely, when a first adhesive portion having a low modulus is used to reduce the likelihood of fatigue failure of the second adhesive portion, the durability of the flexible display in the first portion may decrease.

However, the problems that the disclosure seeks to solve are not limited to the aforementioned problems, and may be expanded in various ways without departing from the spirit and scope of the disclosure.

### Solution to Problem

Aspects of the disclosure are to address at least the above-mentioned problems and/or disadvantages and to provide at least the advantages described below. Accordingly, an aspect of the disclosure is to provide an electronic device including a flexible display.

Additional aspects will be set forth in part in the description which follows and, in part, will be apparent from the description, or may be learned by practice of the presented embodiments.

In accordance with an aspect of the disclosure, an electronic device is provided. The electronic device includes a first housing and a second housing configured to move relative to the first housing, and a flexible display including a first portion and a second portion, wherein at least part of the second portion is drawn into or withdrawn from an inner space of the electronic device in accordance with the second housing moving with respect to the first housing, wherein the flexible display includes a first window layer, a second window layer, and at least two adhesive layers including a first adhesive layer and a second adhesive layer disposed between the first window layer and the second window layer, the at least two adhesive layers configured to adhesively attach the first window layer to the second window layer, wherein the first adhesive layer includes a first adhesive portion corresponding to the first display portion and a second adhesive portion corresponding to the second display portion, wherein a modulus of the second adhesive portion is lower than the modulus of the first adhesive portion, and a modulus of the second adhesive layer is equal to or lower than the modulus of the first adhesive portion.

In accordance with another aspect of the disclosure, a flexible display disposed in an electronic device in which the first housing and the second housing are movably coupled and having a first portion and a second portion configured to be at least partially slid into an inner space of the electronic device or slid out from the inner space based on the movement of the second housing relative to the first housing is provided. The flexible display includes a first window layer, a second window layer disposed on the first window layer, and at least two adhesive layers including a first adhesive layer and a second adhesive layer, the first adhesive layer being disposed between the first window layer and the second window layer to bond the first window layer to the second window layer, wherein the first adhesive layer includes a first adhesive portion corresponding to the first portion of the flexible display and a second adhesive portion corresponding to the second portion of the flexible display, wherein the second adhesive portion has a modulus lower than a modulus of the first adhesive portion, and wherein the second adhesive layer has a modulus is equal to or lower than the modulus of the first adhesive portion.

### Advantageous Effects of Invention

Various embodiments of the disclosure provide an additional adhesive layer between the first window layer and the second window layer. The additional adhesive layer enhances the durability of the flexible display or reduce the likelihood of failure of an adhesive member (e.g., the second adhesive portion) positioned in the second portion of the flexible display.

Accordingly, the flexible display of the disclosure allows natural slip between the layers and is improved in durability against external impacts.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIGS. 2A and 2B illustrate front and rear views of an electronic device in a slide-in state according to various embodiments of the disclosure;

FIGS. 3A and 3B illustrate front and rear views of the electronic device in a slide-out state according to various embodiments of the disclosure;

FIG. 4 is an exploded perspective view of an electronic device according to an embodiment of the disclosure;

FIG. 5A is a cross-sectional view of the electronic device taken along line 5a-5a in FIG. 2A according to an embodiment of the disclosure;

FIG. 5B is a cross-sectional view of the electronic device taken along line 5b-5b in FIG. 3A according to an embodiment of the disclosure;

FIG. 6 is an exploded perspective view of a flexible display according to an embodiment of the disclosure;

FIGS. 7A, 7B, and 7C are cross-sectional views of a flexible display cut along line 5b-5b of FIG. 3A according to various embodiments of the disclosure;

FIG. 8A is a view illustrating stress applied to the first adhesive layer disposed between the first window layer and the second window layer according to an embodiment of the disclosure;

FIG. 8B is a view illustrating stress applied to the first adhesive layer when the second adhesive layer is disposed between the first window layer and the first adhesive layer according to an embodiment of the disclosure;

FIG. 9A is a view illustrating stress applied to the first adhesive layer disposed between the first window layer and the second window layer according to an embodiment of the disclosure;

FIG. 9B is a view illustrating stress applied to the first adhesive layer when the second adhesive layer is disposed between the first window layer and the first adhesive layer according to an embodiment of the disclosure;

FIGS. 10A, 10B, and 10C are views illustrating in which the second adhesive layer is disposed between the second window layer and the first adhesive layer according to various embodiments of the disclosure;

FIGS. 11A, 11B, and 11C are view illustrating a laminated state in which a second adhesive layer, a first adhesive layer, and a third adhesive layer are laminated according to various embodiments of the disclosure;

FIGS. 12A, 12B, and 12C are views illustrating an embodiment in which a second adhesive layer disposed between the first adhesive layer and the first window layer includes a plurality of adhesive members having different moduli, according to various embodiments of the disclosure;

FIGS. 13A and 13B are a front view and a rear view of an electronic device in an unfolded state according to various embodiments of the disclosure;

FIGS. 14A and 14B are a front view and a rear view of the electronic device in a folded state according to various embodiments of the disclosure;

FIG. 15A is a schematic front view of a multi-foldable electronic device in an unfolded state according to an embodiment of the disclosure;

FIG. 15B is a schematic rear view of the multi-foldable electronic device in an unfolded state according to an embodiment of the disclosure;

FIG. 16 is a view schematically illustrating a multi-foldable electronic device in a state in which a first housing is folded relative to a second housing according to an embodiment of the disclosure; and

FIG. 17 is a view schematically illustrating the multi-foldable electronic device in a state in which the first housing and a third housing are folded relative to the second housing according to an embodiment of the disclosure.

The same reference numerals are used to represent the same elements throughout the drawings.

### MODE FOR THE INVENTION

The following description with reference to the accompanying drawings is provided to assist in a comprehensive understanding of various embodiments of the disclosure as defined by the claims and their equivalents. It includes various specific details to assist in that understanding, but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but are merely used by the inventor to enable a clear and consistent understanding of the disclosure. Accordingly, it should be apparent to those skilled in the art that the following description of various embodiments of the disclosure is provided for illustration purposes only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

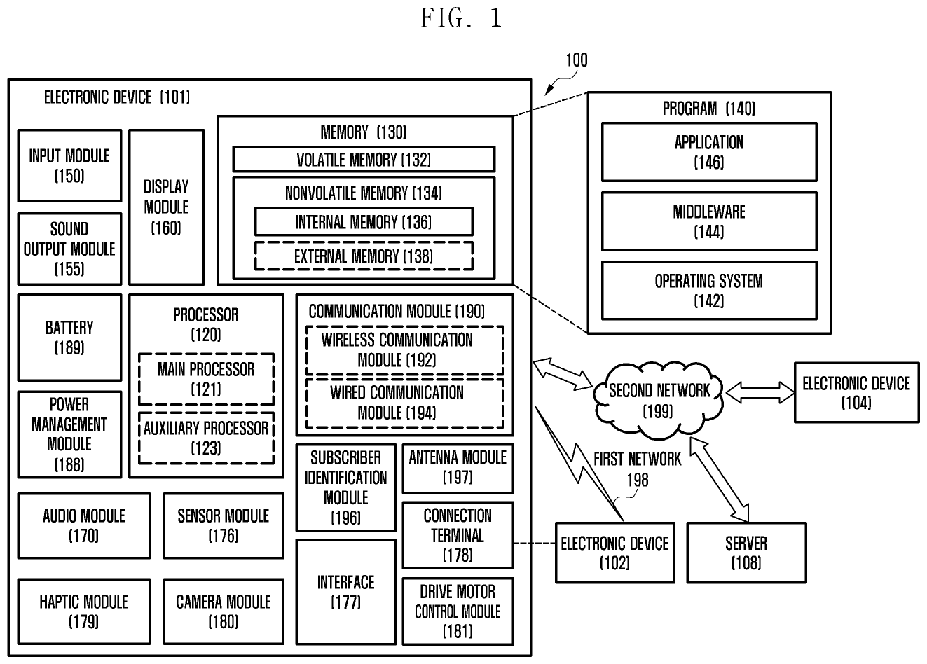

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls.

According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a fifth-generation (5G) network, after a fourth-generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IOT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

According to various embodiments, the sensor module 176 may include a moving distance detection sensor configured to detect the moving distance of the second housing (e.g., the second housing 220 in FIG. 4) from the first housing (e.g., the first housing 210 in FIG. 4) of an electronic device (e.g., the electronic device 200 in FIG. 4). In an embodiment, the sensor module 176 may detect a first state, which is a slide-in state, in which the second housing 220 is fully slid into the first housing 210, a second state, which is a slide-out state, in which the second housing is fully slid out from the first housing 210, or an intermediate state between the slide-in state and the slide-out state. In some embodiments, the processor 120 may be configured to detect the moving distance in real time via the sensor module 176 while the second housing 220 is moving from the first housing 210, and to control the display module 160 to display an object corresponding to a changing display area via a flexible display (e.g., the flexible display 230 in FIG. 4). In an embodiment, the electronic device 101 may include a drive motor control module 181 configured to control the operation of a drive motor (e.g., a DC motor or a stepping motor) (e.g., the drive motor 260 in FIG. 4) disposed inside the electronic device. In some embodiments, the processor 120 may replace the drive motor control module 181.

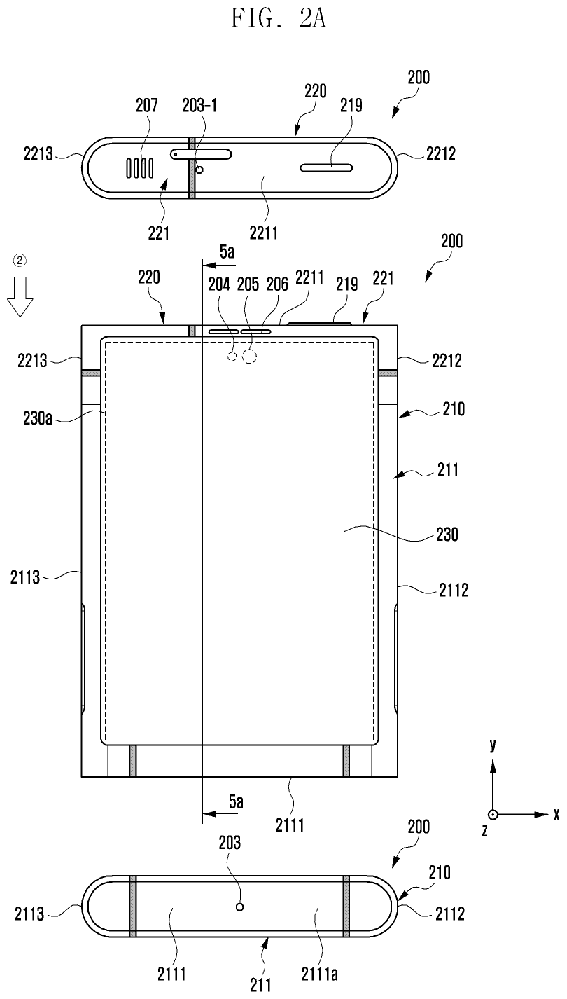

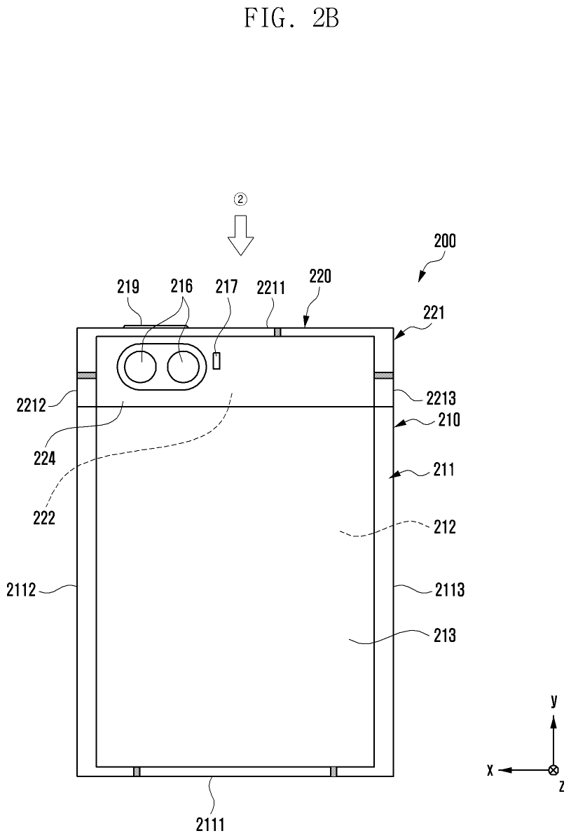

FIGS. 2A and 2B illustrate front and rear views of an electronic device in a slide-in state according to various embodiments of the disclosure.

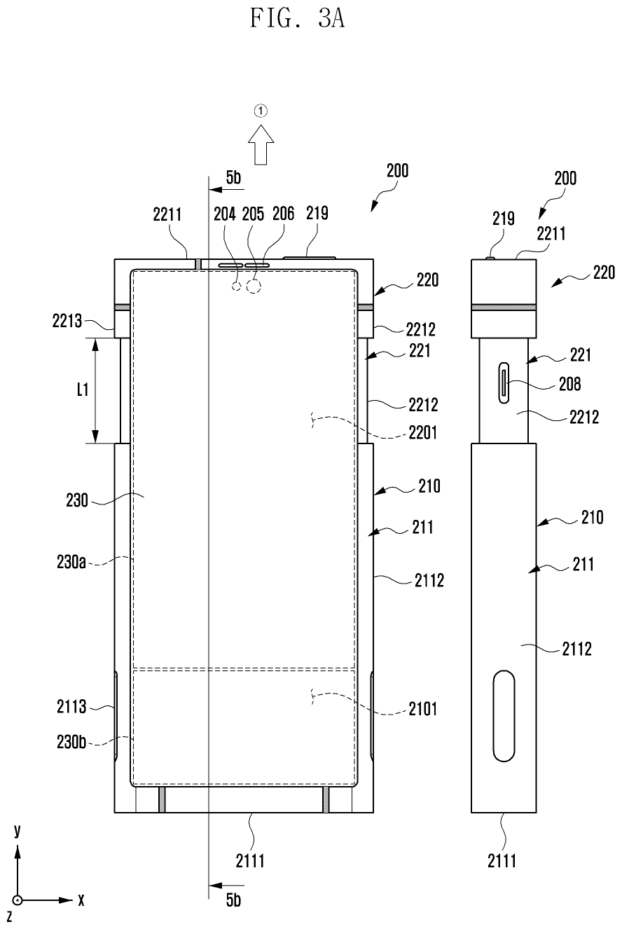

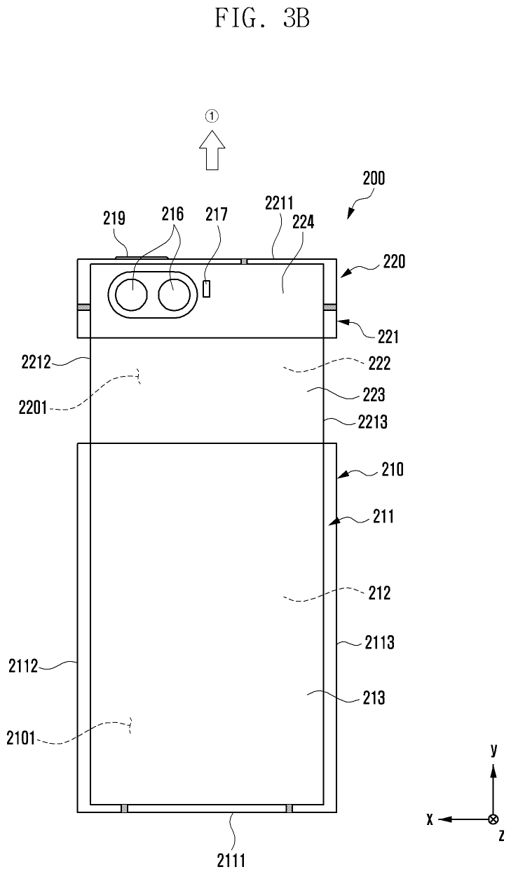

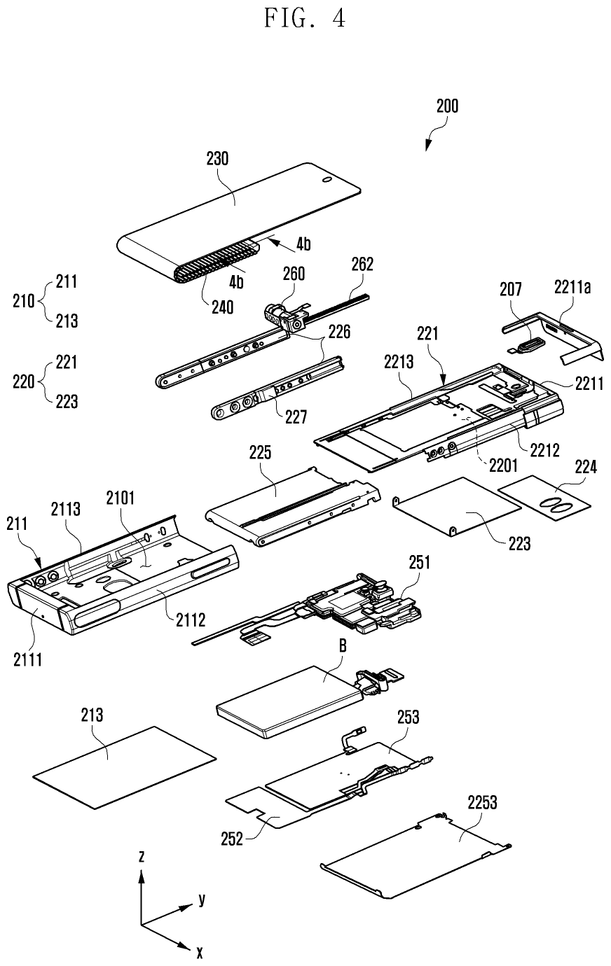

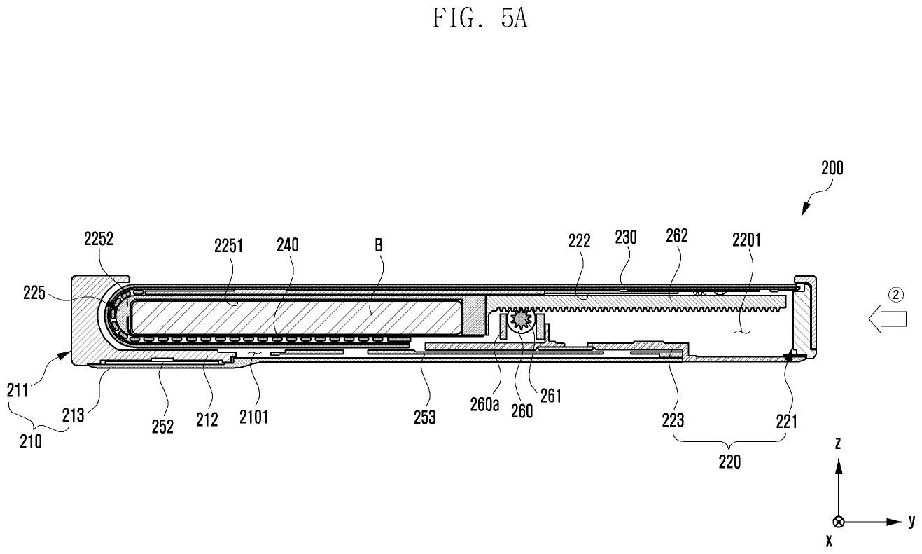

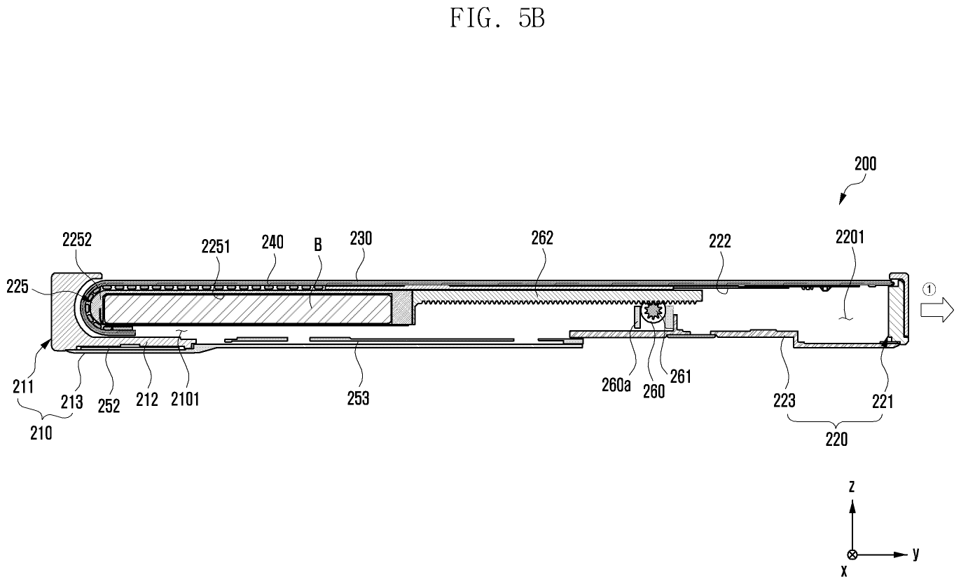

FIGS. 3A and 3B illustrate front and rear views of the electronic device in a slide-out state according to various embodiments of the disclosure.

The electronic device 200 of FIGS. 2A, 2B, 3A, and 3B may be at least partially similar to the electronic device 101 of FIG. 1 or may further include other embodiments of the electronic device.

Referring to FIGS. 2A, 2B, 3A, and 3B, an electronic device 200 may include a first housing 210 (e.g., a book cover or a first housing structure), a second housing 220 (e.g., a front cover or a second housing structure) slidably coupled to the first housing 210 in a predetermined direction (e.g., direction \textcircled{1} or direction \textcircled{2} (e.g., ±y-axis direction), and a flexible display 230 (e.g., a rollable display, an expandable display, or a stretchable display) disposed to be supported by at least a portion of the first housing 210 and the second housing 220. The second housing 220 may be slidably coupled to the first housing 210 so as to slide out along a first direction (direction \textcircled{1}) relative to the first housing 210 or slide in along a second direction (direction \textcircled{2}), which is opposite to the first direction (direction \textcircled{1}). The electronic device 200 may transition to the first state, which is the slide-in state, as at least a portion of the second housing 220 is accommodated in at least a portion of a first space 2101 formed through the first housing 210. The electronic device 200 may transition to the second state, which is the slide-out state, as at least a portion of the second housing 220 moves outward (e.g., in direction \textcircled{1}) from the first space 2101. In the slide-out state, the electronic device 200 may include a support member (e.g., the support member 240 in FIG. 4) (e.g., a bendable member, a multi-joint hinge module, a multi-bar assembly, a support bar assembly, or multiple bars), which at least partially forms the same plane as at least a portion of the second housing 220, and in the slide-in state, is at least partially accommodated in the first space 2101 of the first housing 210 in a bending manner. At least a portion of the flexible display 230 may be disposed to be supported by at least a portion of the second housing 220. The remaining portion of the flexible display 230 may be disposed to be at least partially supported by the support member (e.g., the support member 240 in FIG. 4). The support member (e.g., the support member 240 in FIG. 4) may be disposed in a manner of being attached to the rear surface of the flexible display 230. In the slide-in state, at least a portion of the flexible display 230 may be accommodated into the first space 2101 of the first housing 210 in a bending manner while being supported by the support member (e.g., the support member 240 in FIG. 4), thereby being disposed to be invisible from the outside. In the slide-out state, at least a portion of the flexible display 230 may be disposed to be visible from the outside while being supported by the support member (e.g., the support member 240 in FIG. 4), which at least partially forms the same plane as the second housing 220.

The first housing 210 may include a first side surface member 211, and the second housing 220 may include a second side surface member 221. The first side surface member 211 may be disposed at the bottom side of the electronic device 200 and may include a first side surface 2111 having a first length, a second side surface 2112 extending in a perpendicular direction (e.g., the y-axis direction) from one end of the first side surface 2111 and having a second length, and a third side surface 2113 extending parallel to the second side surface 2112 from the other end of the first side surface 2111 and having the second length. The first side surface member 211 may be at least partially made of a conductive member (e.g., metal). The first side surface member 211 may be formed by a coupling a conductive member and a non-conductive member (e.g., polymer). The first housing 210 may include a first extension member 212 extending from at least a portion of the first side surface member 211 to at least a portion of the first space 2101. The first extension member 212 may be integrated with the first side surface member 211. According to some embodiments of the disclosure, the first extension member 212 may be provided separately from the first side surface member 211 and structurally coupled to the first side surface member 211.

The second side surface member 221 may be disposed at the upper side of the electronic device 200 and may include a fourth side surface 2211 having a third length, a fifth side surface 2212 extending in a perpendicular direction (e.g., the −y-axis direction) from one end of the fourth side 2211 to correspond to the second side surface 2112 and having a fourth length, and a sixth side surface 2213 extending in a direction parallel to the fifth side surface 2212 from the other end of the fourth side 2211 to correspond to the third side surface 2113 and having the fourth length. In an embodiment, the second side surface member 221 may be at least partially made of a conductive member (e.g., metal). The second side surface member 221 may be formed by coupling a conductive member and a non-conductive member (e.g., polymer). At least a portion of the second side surface member 221 may include a second extension member 222 extending to at least a portion of a second space 2201 in the second housing 220. The second extension member 222 may be integrated with the second side surface member 221. According to some embodiments of the disclosure, the second extension member 222 may be provided separately from the second side surface member 221 and structurally coupled to the second side surface member 221.

The second side surface 2112 and the fifth side surface 2212 may be slidably coupled to each other. Similarly, the third side surface 2113 and the sixth side surface 2213 may be slidably coupled to each other. In the slide-in state, a portion of the fifth side surface 2212 may overlap the second side surface 2112, thereby being disposed to be substantially invisible from the outside. In the slide-in state, the remaining portion of the fifth side surface 2212 may be disposed to be visible from the outside. In the slide-in state, the fifth side surface 2212 may overlap the second side surface 2112, thereby being disposed to be substantially invisible from the outside. In the slide-in state, a portion of the sixth side surface 2213 may overlap the third side surface 2113, thereby being disposed to be substantially invisible from the outside. In the slide-in state, the remaining portion of the sixth side surface 2213 may be disposed to be visible from the outside. In the slide-in state, the sixth side surface 2213 may overlap the third side surface 2113, thereby being disposed to be substantially invisible from the outside. A portion of the second extension member 222 may be disposed to be visible from the outside in the slide-in state. In the slide-in state, the second extension member 222 may overlap the first extension member 212, thereby being disposed to be substantially invisible from the outside.

The first housing 210 may include a first rear surface cover 213 coupled to at least a portion of the first side surface member 211. The first rear surface cover 213 may be disposed to be coupled to at least a portion of the first extension member 212. According to some embodiments of the disclosure, the first rear cover 213 may be integrated with the first side surface member 211. The first rear cover 213 may be made of a polymer, coated or colored glass, ceramic, metal (e.g., aluminum, stainless steel (STS), or magnesium), or a combination of at least two of these materials. The first rear surface cover 213 may extend to at least a portion of the first side surface member 211. According to other embodiments of the disclosure, the first rear surface cover 213 may be omitted, and at least a portion of the first extension member 212 may replace the first rear surface cover 213.

The second housing 220 may include a second rear surface cover 223 coupled to at least a portion of the second side surface member 221. The second rear surface cover 223 may be disposed by being coupled to at least a portion of the second extension member 222. The second rear surface cover 223 may be integrated with the second side surface member 221. The second rear surface cover 223 may be made of polymer, coated or tinted glass, ceramic, metal (e.g., aluminum, stainless steel (STS), or magnesium), or a combination of at least two of these materials. According to some embodiments of the disclosure, the second rear surface cover 223 may extend to at least a portion of the second side surface member 221. According to other embodiments of the disclosure, the second rear surface cover 223 may be omitted, and at least a portion of the second extension member 222 may replace the second rear surface cover 223. According to some embodiments of the disclosure, the second extension member 222 may be omitted, and the second rear surface cover 223 may replace the second extension member 222. The second housing 220 may include a window cover 224 disposed at least partially on the second rear surface cover. The window cover 224 may be disposed in an area exposed to the outside of the second housing 220 in the slide-in state and may be made of a material that facilitates the detection of the external environment through at least one camera module 216 and/or sensor module 217 disposed in the inner space 2201 of the second housing 220. For example, the window cover 224 may be made of glass and/or a polymer material in which at least an area corresponding to the camera module 216 and/or the sensor module 217 is formed to be transparent. The electronic device 200 may further include a cover member 2111a disposed to cover at least a portion of the first side surface 2111 of the first housing 210.

The flexible display 230 may include a first portion 230a (e.g., a flat portion) that is always visible from the outside, and a second portion 230b (e.g., a bendable portion or a bending portion) that extends from the first portion 230a and is at least partially bent and accommodated into the first space 2101 of the first housing 210 to be invisible from the outside in the slide-in state. At least a portion of the first portion 230a may be disposed to be supported by the second housing 220, and the remaining portion of the first portion 230a and the second portion 230b may be disposed to be at least partially supported by a support member (e.g., the support member 240 in FIG. 4). In the state in which the second housing 220 is slid out along the first direction (direction 1), the second portion 230b of the flexible display 230 may form substantially the same plane as the first portion 230a while being supported by the support member (e.g., the support member 240 in FIG. 4), and may be disposed to be visible from the outside. In the state in which the second housing 220 is slid in along the second direction (direction (2), the second portion 230b of the flexible display 230 may be accommodated into the first space 2101 of the first housing 210 in a bending manner and may be disposed to be invisible from the outside. Accordingly, in the flexible display 230, the display area may be variable as the second housing 220 is moved in a sliding manner from the first housing 210 along a predetermined direction (e.g., the ty-axis direction).

The flexible display 230 may have a first display area (e.g., an area corresponding to the first portion 230a) in the slide-in state (e.g., the first state). In the flexible display 230, when the second housing 220 transitions to the slide-out state (e.g., the second state), in which the second housing 220 moves by a first length L1 (e.g., a sliding stroke) relative to the first housing 210, in the flexible display 230, a second display area (e.g., an area corresponding to the second portion 230b) corresponding to the first length L1 may be additionally secured in addition to the first display area. For example, when the flexible display 230 transitions from the slide-in state to the slide-out state, the display area may be expanded.

The electronic device 200 may include at least one of an input device (e.g., a microphone 203-1) disposed in the second space 2201 of the second housing 220, a sound output device (e.g., a phone call receiver 206 and/or a speaker 207), sensor modules 204 and 217, a camera module (e.g., the first camera module 205 or the second camera module 216), a connector port 208, a key input device 219, or an indicator (not illustrated). The electronic device 200 may include another input device (e.g., the microphone 203) disposed in the first housing 210. According to some embodiments of the disclosure, the electronic device 200 may be configured such that at least one of the above-mentioned components is omitted or other components are additionally included. In some embodiments, at least one of the above-mentioned components may be disposed in the first space 2101 of the first housing 210.

The input device may include a microphone 203-1. The input device (e.g., the microphone 203-1) may include multiple microphones arranged to detect the direction of sound. The sound output device may include, for example, a call receiver 206 and a speaker 207. According to an embodiment of the disclosure, regardless of the slide-in/slide-out state, the speaker 207 may face the outside through at least one speaker hole provided in the second housing 220 at a position always exposed to the outside (e.g., in the fourth side surface 2211). In the slide-out state, the connector port 208 may face the outside through a connector port hole provided in the second housing 220. In the slide-in state, the connector port 208 may be covered so as to be invisible from the outside. According to some embodiments of the disclosure, in the slide-in state, the connector port 208 may face the outside through an opening provided in the first housing 210 to correspond to the connector port hole. The call receiver 206 may include a speaker that operates without a separate speaker hole (e.g., a piezo speaker).

The sensor modules 204 and 217 may generate electrical signals or data values corresponding to an internal operating state or an external environmental state of the electronic device 200. The sensor modules 204 and 217 may include, for example, a first sensor module 204 (e.g., a proximity sensor or an illuminance sensor) disposed on the front surface of the electronic device 200 and/or a second sensor module 217 (e.g., a heart rate monitoring (HRM) sensor) disposed on the rear surface of the electronic device 200. The first sensor module 204 may be disposed under the flexible display 230 in the front surface of the electronic device 200. The first sensor module 204 and/or the second sensor module 217 may include at least one of a proximity sensor, an illuminance sensor, a time-of-flight (TOF) sensor, an ultrasonic sensor, a fingerprint recognition sensor, a gesture sensor, a gyro sensor, an atmospheric pressure sensor, a magnetic sensor, an acceleration sensor, a grip sensor, a color sensor, an infrared (IR) sensor, a biometric sensor, a temperature sensor, or a humidity sensor.

The camera module may include a first camera module 205 disposed on the front surface of the electronic device 200 and a second camera module 216 disposed on the rear surface of the electronic device 200. In an embodiment, the electronic device 200 may include a flash (not illustrated) positioned near the second camera module 216. The camera modules 205 and 216 may include one or more lenses, an image sensor, and/or an image signal processor. In an embodiment, the first camera module 205 may be disposed under the flexible display 230 and may be configured to capture a subject through a portion of an active area (e.g., a display area) of the flexible display 230.

The first camera module 205 among the camera modules and the first sensor module 204 among the sensor modules 204 and 217 may be disposed to detect the external environment through the flexible display 230. For example, the first camera module 205 or the first sensor module 204 may be disposed in the second space 2201 in the second housing 220 to be in contact with the external environment through a transmissive area or a perforated opening provided in the flexible display 230. The area of the flexible display 230 that faces the first camera module 205 may be configured as the transmissive area having a predetermined transmittance, as a portion of an active area that displays content. The transmissive area may have a transmittance ranging from about 5% to about 20%. The transmission area may include an area overlapping an effective area (e.g., a field of view area) of the first camera module 205 through which light imaged by an image sensor to generate an image passes. For example, the transmissive area of the flexible display 230 may include an area having a lower pixel density and/or a lower wire density than the surrounding area. For example, the above-mentioned opening may replace the transmissive area. For example, some camera modules 205 may include an under-display camera (UDC). In some embodiments, some sensor modules 204 may be disposed to perform the functions thereof in the second space 2201 in the second housing 220 without being visually exposed through the flexible display 230.

The slide-in operation and/or slide-out operation of the electronic device 200 may be performed automatically. For example, the slide-in operation and/or slide-out operation of the electronic device 200 may be performed through gear engagement between a drive motor (e.g., the drive motor 260 in FIG. 4), which includes a pinion gear (e.g., the pinion gear 261 in FIG. 5A) disposed in the second space 2201 of the second housing 220, and a rack gear (e.g., the rack gear 262 in FIG. 5A), which is disposed in a first space 2101 of the first housing 210, extends at least partially into the second space 2201, and is engaged with the pinion gear (e.g., the pinion gear 261 of FIG. 5A). For example, the processor (e.g., the processor 120 in FIG. 1) of the electronic device 200 may drive a drive motor (e.g., the drive motor 260 of FIG. 4) disposed inside the electronic device 200 when detecting a triggering signal for transitioning from the slide-in state to the slide-out state or from the slide-out state to the slide-in state. In an embodiment, the triggering signal may include a signal generated by the selection (e.g., touch) of an object displayed on the flexible display 230 or a signal generated by the operation (e.g., pressing) of a physical button (e.g., a key button) included in the electronic device 200.

The electronic device 200 may have a structure in which the second housing 220 is slid in and/or slid out relative to the first housing 210 along the length direction of the electronic device 200 (e.g., the vertical direction) (e.g., the ty-axis direction), but is not limited thereto. For example, the electronic device 200 may have a structure in which the second housing 220 is slid in and/or slid out relative to the first housing 210 along the width direction perpendicular to the length direction of the electronic device 200 (e.g., the horizontal direction) (e.g., the +x-axis direction). According to some embodiments of the disclosure, in the electronic device 200, the length of the first side surface 2111 of the first housing 210 may be greater than the length of the second side surface 2112. In this case, correspondingly, the length of the fourth side surface 2211 of the second housing 220 may also be greater than the length of the fifth side surface 2212.

FIG. 4 is an exploded perspective view of an electronic device according to an embodiment of the disclosure.

In describing the electronic device 200 of FIG. 4, components that are substantially the same as those of the electronic device 200 of FIGS. 2A, 2B, 3A, and 3B may be assigned with the same reference numerals, and a detailed description thereof may be omitted.

Referring to FIG. 4, the electronic device 200 may include a first housing 210 including a first space 2101, a second housing 220 slidably coupled to the first housing 210 and including a second space 2201, a support member 240 (e.g., a bendable member, a support bar assembly, or a multi-bar assembly) fixed to at least a portion of the second housing 220 and at least partially accommodated in the first space 2101 in a bendable manner according to the slide-in operation, a flexible display 230 disposed to be supported by at least a portion of the support member 240 and the second housing 220, and a driver (e.g., a drive module or a drive mechanism) configured to drive the second housing 220 in the slide-in direction (e.g., the −y-axis direction) and/or the slide-out direction (e.g., the y-axis direction) from the first housing 210. In the electronic device 200, the first housing 210 may be slidably coupled to the second housing 220 depending on the disposition position of the driver (e.g., the drive motor 260 and the rack gear 262). The first housing 210 may include a first side surface member 211 and a first rear surface cover 213 (e.g., a first rear bracket) coupled to at least a portion of the first side surface member 211. The first space 2101 may be defined by the coupling of the first side surface member 211 and the first rear surface cover 213. The electronic device 200 may include a side surface cover 2211a (e.g., a dielectric cover) disposed on the fourth side surface 2211 of the second side surface member 221.

According to various embodiments, the second housing 220 may include a second side surface member 221 and a second rear surface cover 223 (e.g., a second rear bracket or a window cover) coupled to at least a portion of the second side surface member 221. In an embodiment, the second space 2201 may be defined by the coupling of the second side surface member 221 and the second rear surface cover 223. In an embodiment, the second housing 220 may be coupled to the second side surface member 221 and may include a window cover 224 forming at least a portion of the rear surface of the second housing 220.

The driver (e.g., a drive module) may be disposed in the second space 2201 and may include a drive motor 260 including a pinion gear (e.g., the pinion gear 261 in FIG. 5A) and a rack gear 262 disposed to be gear-engaged with the pinion gear 261, fixed to a support bracket 225 disposed in the first space 2101, and extending from the first space 2101 to the second space 2201 The electronic device 200 may further include a speed reduction module (e.g., a reduction gear assembly) structurally coupled to the drive motor so as to reduce the rotational speed and increase the driving force by being engaged with the drive motor 260. The drive motor 260 may be disposed in the second space 2201 of the second housing 220 to be supported by at least a portion of the second side surface member 221 (e.g., the second extension member 222 in FIG. 5A). The drive motor 260 may be disposed to be supported through a motor bracket (e.g., the motor bracket 260a in FIG. 5A) fixed to the second extension member 222. The rack gear 262 may be guided in the sliding direction (e.g., the ty-axis direction) through the motor bracket 260a. Accordingly, when the electronic device 200 is assembled, the pinion gear (e.g., the pinion gear 261 in FIG. 5A) may remain in a gear-engaged state with the rack gear 262, and as the pinion gear 261, which receives a driving force from the drive motor 260, moves along the rack gear 262, the second housing 220 may move in the slide-in direction (e.g., the −y-axis direction) or the slide-out direction (e.g., the y-axis direction) relative to the first housing 210.

The electronic device 200 may include a support bracket 225 fixed in the first space 2101 of the first housing 210. The electronic device 200 may include a pair of guide rails 226 (e.g., a linear motion (LM) guide) that are fixed to both sides of the support bracket 225 to guide both ends of the support member 240 in the sliding direction while simultaneously guiding the second housing 220 in the sliding direction. The support bracket 225 and the pair of guide rails 226 may be fixed to the first housing 210 through fastening members such as screws. The support bracket 225 may include a battery seating portion (e.g., the battery seating portion 2251 in FIG. 5A) configured to accommodate a battery B and a support portion (e.g., the support portion 2252 in FIG. 5A) provided at one end of the battery seating portion 2251 to support the rear surface of the support member 240 that bends during the sliding operation of the second housing 220. The support portion 2252 may have a curved outer surface to smoothly guide the support member 240. The support bracket 225 and the guide rails 226 may be fixed in the first space 2101 of the first housing 210 through fastening members such as screws. The electronic device 200 may further include a battery cover 2253 coupled to the support bracket 225 to cover the mounted battery B. According to some embodiments of the disclosure, the battery cover 2253 may be omitted. The rack gear 262 may be fixed through fastening members such as screws so as to extend from the outer surface of the support bracket 225 toward the second space 2201. The rack gear 262 may be disposed at the center (e.g., a centrally symmetrical position) of the support bracket 225 so as to traverse the center of the electronic device 200 along the sliding direction of the second housing 220 (e.g., the +y-axis direction). This central disposition may reduce power consumption by decreasing the increase in driving resistance caused by eccentricity during the sliding operation.

The electronic device 200 may include at least one electrical component (or electronic component) disposed in the second space 2201. The at least one electrical component may include a first substrate 251 (e.g., a substrate assembly or a main substrate) (e.g., stacked substrates). The at least one electrical component may be disposed in the first space 2101 of the first housing 210.

The electronic device 200 may include a second substrate 252 (e.g., a sub-substrate) and an antenna member 253, which are disposed between a first extension member (e.g., first extension member 212 in FIG. 5A) and the first rear surface cover 213 in the first housing 210. The second substrate 252 and the antenna member 253 may be disposed on at least a portion of the first extension member 212. The second substrate 252 and the antenna member 253 may be electrically connected to the first substrate 251 via at least one electrical connection member (e.g., a flexible printed circuit board (FPCB) or a flexible RF cable (FRC)). The antenna member 253 may include a multi-function coil or multi-function core (MFC) antenna configured to execute a wireless charging function, a neat field communication (NFC) function, and/or an electronic payment function. The second substrate 252 and/or the antenna member 253 may extend from the first space 2101 to the second space 2201 and may be electrically connected to the first substrate 251 through a flexibly deformable flexible substrate (a flexible printed circuit board (FPCB)).

The electronic device 200 may include a pair of guide blocks 227 fixed to the second housing 220 and slidably coupled to a pair of guide rails 226. The second housing 220 may be slid out from the first housing 210 by a specific distance (e.g., the first distance L1 of FIG. 3A) through the slidable coupling of the guide rails 226 and the guide blocks 227.

FIG. 5A is a cross-sectional view of the electronic device taken along line 5a-5a in FIG. 2A according to an embodiment of the disclosure.

FIG. 5B is a cross-sectional view of the electronic device taken along line 5b-5b in FIG. 3A according to an embodiment of the disclosure.

In describing the electronic device 200 of FIGS. 5A and 5B, the same reference numerals are assigned to components that are substantially the same as those of the electronic device 200 of FIG. 4A, and detailed descriptions thereof may be omitted.

Referring to FIGS. 5A and 5B, the electronic device 200 may include a first housing 210 having a first space 2101, a second housing 220 having a second space 2201, a support member 240 connected to the second housing 220 and at least partially accommodated in the first space 2101 in the slide-in state, a flexible display 230 disposed to be supported by at least a portion of the support member 240 and at least a portion of the second housing 220, a rack gear 262 fixed in the first space 2101 and extending into the second space 2201, and a drive motor 260 disposed in the second space 2201 and including a pinion gear 261 gear-engaged with the rack gear 262. The drive motor 260 may automatically move the second housing 220 in the slide-out direction (direction \textcircled{1}) or the slide-in direction (direction (2)) relative to the first housing 210 through the gear engagement between the pinion gear 261 and the rack gear 262. By changing the disposition of the drive motor 260 and the rack gear 262, the first housing 210 may be automatically moved in the slide-out direction (direction (2) or the slide-in direction (direction \textcircled{1}) from the second housing 220. The first housing 210 may include a first side surface member 211 and a first rear surface cover 213 coupled to a first extension member 212 extending from the first side surface member 211. The second housing 220 may include a second side surface member 221 and a second rear surface cover 223 coupled to a second extension member 222 extending from the second side surface member 221.

A portion of the second housing 220 may be accommodated in the first space 2101 of the first housing 210 in the slide-in state of the electronic device 200 (the state illustrated in FIG. 5A). At least a portion of the flexible display 230 may be accommodated in the first space 2101 in a bending manner together with the support member 240, thereby being disposed to be invisible from the outside. In this case, a first display area of the flexible display 230 (e.g., the display area corresponding to the first portion 230a in FIG. 3A) may be exposed to the outside.

At least a portion of the second housing 220 may transition to the slide-out state in which the second housing is at least partially moved to the outside from the first housing 210 along the first direction (direction \textcircled{1}) through the driving of the drive motor 260. In the slide-out state of the electronic device 200 (the state illustrated in FIG. 5B), the flexible display 230 may be supported by the support bracket 225 and may move together with the support member 240, thereby exposing the portion accommodated in the first space 2101 to be at least partially visible from the outside. In this case, in the flexible display 230, a second display area (e.g., a display area including the first portion 230a and the second portion 230b in FIG. 3A) that is greater than the first display area may be exposed to the outside. In some embodiments, the rack gear 262 may be disposed in the second housing 220, and the drive motor 260 including the pinion gear 261 may be disposed in the first housing 210.

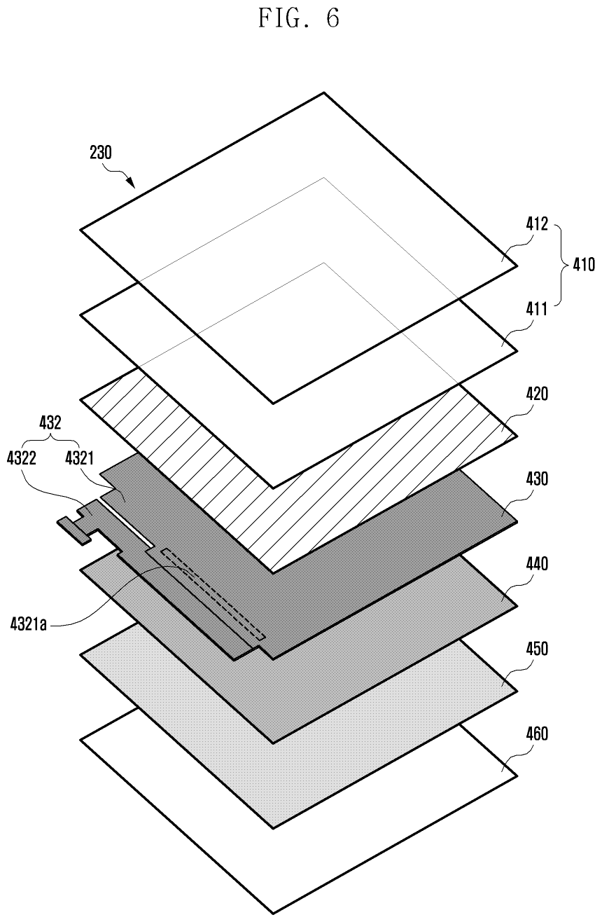

FIG. 6 is an exploded perspective view of a flexible display according to an embodiment of the disclosure.

Referring to FIG. 6, an electronic device 200 may include a first housing 210, a second housing 220 slidably coupled to the first housing 210, and a flexible display 230 disposed to be supported by the first housing 210 and the second housing 220. In the slide-in state, the flexible display 230 may include a first portion 230a (e.g., a planar portion) that is always visible from the outside and a second portion 230b (e.g., a bendable portion) extending from the first portion 230a and at least partially accommodated in the inner space (e.g., the first space 2101 in FIG. 5A) of the electronic device 200.

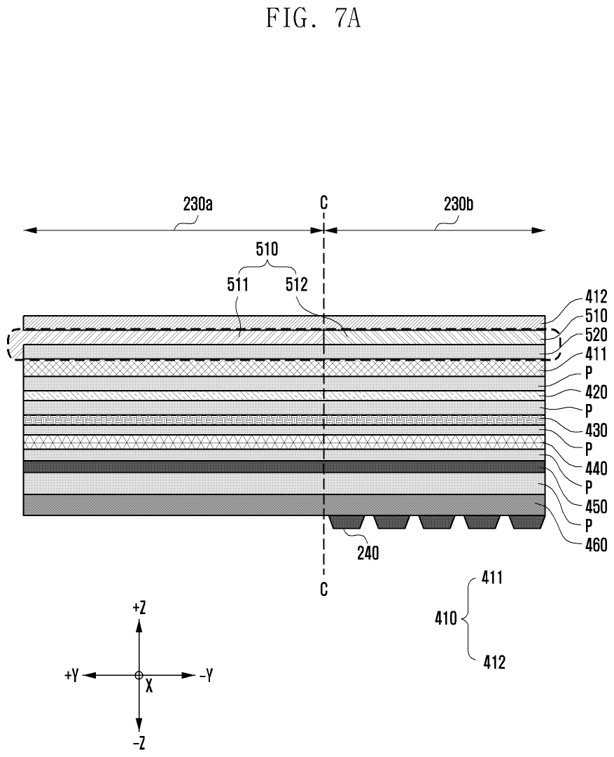

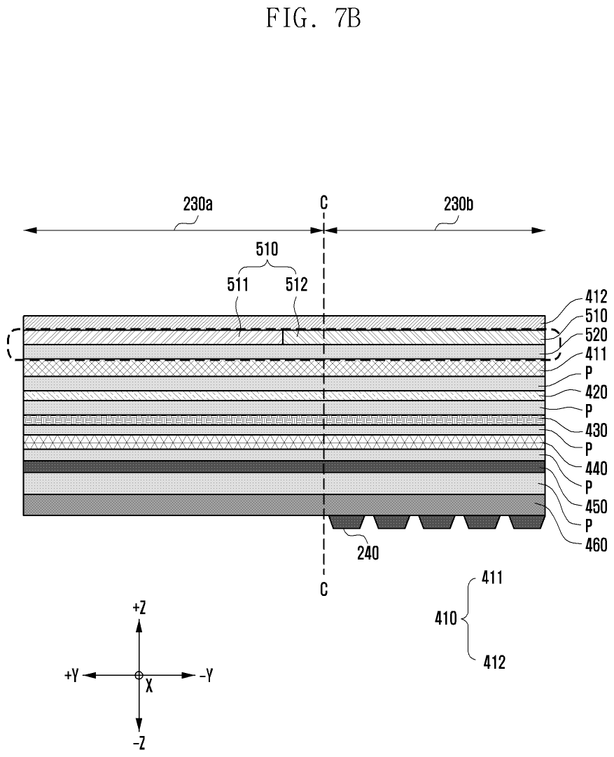

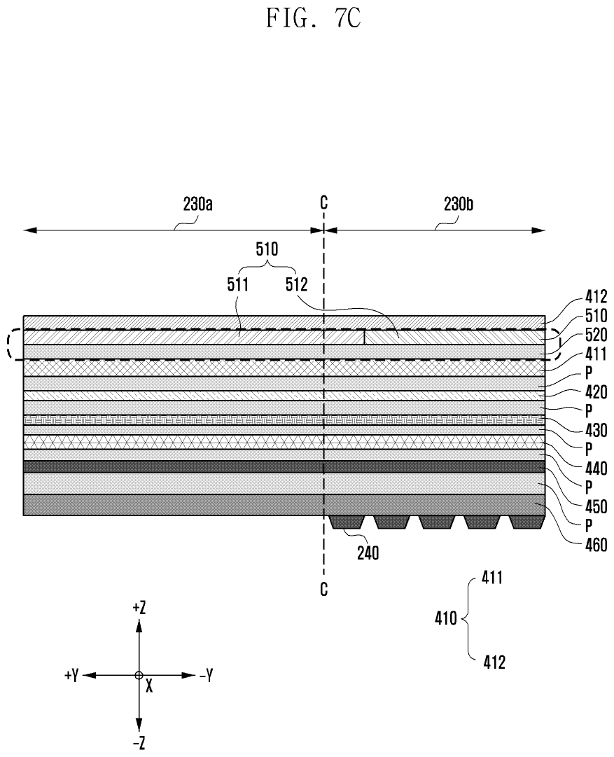

The flexible display 230 may include a window layer 410, a polarizer (POL) 420 (e.g., a polarizing film) disposed on the rear surface of the window layer 410, a display panel 430, a polymer layer 440, at least one functional layer 450, and a support plate 460. The electronic device 200 may include a support member 240 disposed under the functional layer 450 to correspond to at least the second portion 230b. The support member 240 may include multiple bars 241 attached at predetermined intervals on the rear surface of the support plate 460 through an adhesive layer P (e.g., adhesive layer P of FIG. 7A). The window layer 410, the polarizer 420, the display panel 430, the polymer layer 440, the support plate 460, and the support member 240 may be attached to one another through an adhesive layer P (e.g., an adhesive or bonding agent). For example, the adhesive layer P may include a pressure-sensitive adhesive (PSA), an optical clear adhesive (OCA), an optical clear resin (OCR), a heat-reactive adhesive, a general adhesive, or a double-sided tape. A first adhesive layer 510, a second adhesive layer 520, 620, or 720, and a third adhesive layer 630, which are bonded between a first window layer 411 and a second window layer 412, which is described below, may include a pressure-sensitive adhesive (PSA), an optical clear adhesive (OCA), an optical clear resin (OCR), a heat-reactive adhesive, a general adhesive, or a double-sided tape. At least one of the aforementioned plurality of layers 410, 420, 430, 440, 450, 460, and 240 (e.g., the support plate 460 or the support member 240) may be omitted. For example, when the flexible display 230 is a POL-less display, the polarizer may be omitted, and a transparent reinforcement layer (e.g., a buffer layer) may be further disposed at that position.

The window layer 410 may include a first window layer (e.g., a glass layer or a first layer) 411 and a second window layer (e.g., a protective layer or a second layer) 412 laminated together. The first window layer 411 may be made of glass. The first window layer may include UTG (ultra-thin glass). The second window layer 412 may be made of polymer (e.g., polyethylene terephthalate (PET), polyimide (PI), or thermoplastic polyurethane (TPU)). The flexible display 230 may further include a coating layer formed as a part of the window layer 410 and disposed above the second window layer 412. In such cases, the coating layer may include a hard coating (HC) layer, an anti-reflection/low-reflection (AR/LR) coating layer, a shatter proof (SP) coating layer, or an anti-fingerprint (AF) coating layer. The coating layer may be provided between the first window layer 411 and the second window layer 412, on at least one of the side surface of the second window layer 412 and the rear surface or side surface of the first window layer 411.

The display panel 430 may include a plurality of pixels and a wiring structure (e.g., an electrode pattern). According to an embodiment, the polarizer 420 may selectively allow light, which is generated from a light source of the display panel 430 and vibrates in a predetermined direction, to pass therethrough. According to an embodiment of the disclosure, the display panel 430 and the polarizer 420 may be formed integrally with each other. The flexible display 230 may also include a touch panel (not illustrated).

According to an embodiment, the polymer layer 440 may be disposed under the display panel 430 to provide a dark background for securing visibility of the display panel 430, and may be made of a buffering material for a buffering action. In some embodiments, in order to ensure waterproofing of the flexible display 230, the polymer layer 440 may be removed or disposed under the support plate 460.

The flexible display 230 may further include at least one functional layer 450 disposed below the polymer layer 440. The functional layer 450 may include a protective layer (e.g., a TPU layer) for preventing deformation caused by the bending of the support member 240, a graphite sheet for heat dissipation, an added display, a force-touch FPCB, a fingerprint sensor FPCB, a communication antenna radiator, a conductive/non-conductive tape, or a digitizer. The digitizer may include a plurality of conductive patterns (e.g., coil patterns) disposed on a dielectric substrate (e.g., a dielectric film or a dielectric sheet) to detect a resonant frequency of electromagnetic induction applied from an electronic pen.

The support plate 460 may provide rigidity and flexibility to the flexible display 230. For example, the support plate 460 may be made of a non-metallic sheet material, such as fiber-reinforced plastics (FRP) (e.g., carbon fiber-reinforced plastics (CFRP) or glass fiber-reinforced plastics (GFRP)), having a rigid property to support the display panel 430. The support plate 460 may include a first area (e.g., a planar portion) corresponding to the first portion 230a of the flexible display 230 and a second area (e.g., a bending portion) corresponding to the second portion 230b. The second area may include a plurality of openings arranged at predetermined intervals. The bending characteristics of the second area may be determined by at least one of the size, shape, or arrangement density of at least some of the plurality of openings. The support plate 460 may be made of a metal material such as SUS, Cu, Al, or a metal clad (e.g., a laminated member in which SUS and Al are alternately disposed). The support plate 460 may assist in reinforcing the rigidity of the electronic device 200 and may be used to block ambient noise and to disperse heat emitted from surrounding heat emission components.

The plurality of openings may include through-patterns in the form of slits perforated from the top surface to the rear surface of the second area. The plurality of openings may include recesses having a predetermined depth. The plurality of openings may be formed in a mixed structure of through patterns and recesses.

The flexible display 230 may include a bending portion disposed to fold from the display panel 430 to at least a portion of the rear surface of the flexible display 230. In an embodiment, the bending portion 432 may include an extension 4321 extending from the display panel 430 and including a control circuit 4321a, and a flexible substrate 4322 (e.g., a main FPCB) electrically connected to the extension 4321 and including a plurality of electronic elements. According to an embodiment, the control circuit 4321a may include a display driver IC (DDI) or a touch display driver IC (TDDI) mounted on the extension 4321 having an electrical wiring structure. The bending portion 432 may include a chip-on-panel or chip-on-plastic (COP) structure in which the control circuit 4321a is directly disposed on the extension 4321. The bending portion 432 may include a chip-on-film (COF) structure in which the control circuit 4321a is mounted on a separate connection film (not illustrated) that connects the extension portion 4321 and the flexible substrate 4322. In an embodiment, the plurality of electronic elements may include passive components such as a touch IC, display flash memory, an ESD protection diode, a pressure sensor, a fingerprint sensor, or a decoupling capacitor.

FIGS. 7A, 7B, and 7C are cross-sectional views of a flexible display cut along line 5B-5B of FIG. 3A according to various embodiments of the disclosure.

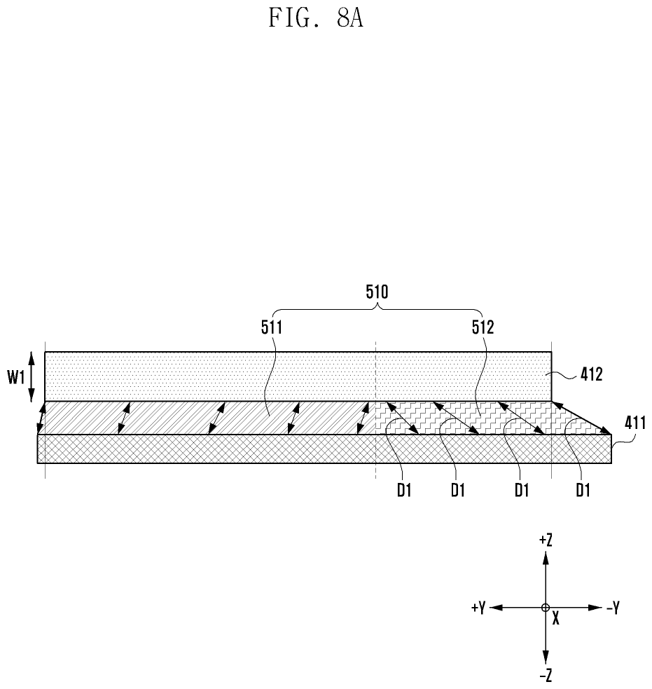

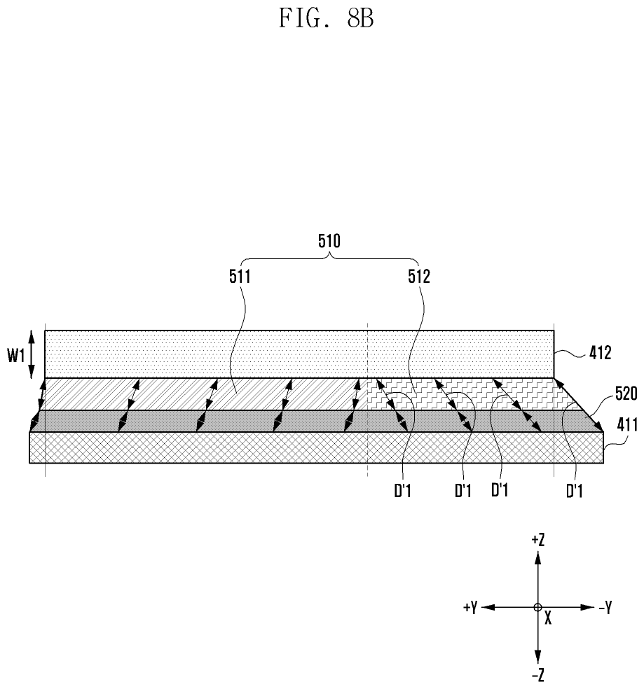

FIG. 8A is a view illustrating stress applied to the first adhesive layer disposed between the first window layer and the second window layer according to an embodiment of the disclosure.

FIG. 8B is a view illustrating stress applied to the first adhesive layer when the second adhesive layer is disposed between the first window layer and the first adhesive layer according to an embodiment of the disclosure.

Referring to FIGS. 7A to 7C, the flexible display 230 may include a first portion 230a (e.g., a planar portion) that is always visible from the outside in the slide-in state and/or the slide-out state of the electronic device and at least partially substantially planar and a second portion 230b (e.g., a bendable portion) extending from the first portion 230a and at least partially accommodated in a bending manner in the first space 2101 of the first housing 210 in the slide-in state of the electronic device 200 so as to be invisible from the outside. At least a portion of the second portion 230b may be visible from the outside in the slide-in state and/or the slide-out state of the electronic device and may form a plane substantially parallel to the first portion 230a.

As illustrated in FIGS. 7A to 7C, at least two adhesive layers (e.g., the first adhesive layer 510) may be disposed between the first window layer 411 and the second window layer 412. The first window layer 411 and the second window layer 412 may be attached to each other through adhesive layers (e.g., the first adhesive layer 510 and the second adhesive layer 520). In an embodiment, when viewed from above the flexible display 230 (e.g., in the −Z direction of FIG. 7A), the first adhesive layer 510 may include a first adhesive portion 511 corresponding at least partially to the first portion 230a of the flexible display 230 and a second adhesive portion 512 corresponding at least partially to both the first portion 230a and the second portion 230b of the flexible display 230. The first adhesive portion 511 and the second adhesive portion 512 may be separate configurations, or may be integrated as a single configuration. The first adhesive portion 511 may be made of a rigid material to provide a certain level of strength to the first portion 230a of the flexible display 230, which is always exposed to the outside. For example, the first adhesive portion 511 may have a relatively higher modulus than the second adhesive portion 512. The second adhesive portion 512 may be made of a soft material to accommodate the slip of the first window layer 411 and/or the second window layer 412 occurring in the second portion 230b of the flexible display 230 during the slide-in or slide-out operation of the electronic device 200. For example, the second adhesive portion 512 may have a relatively lower modulus than the first adhesive portion 511. The first adhesive portion 511 may have a modulus ranging from about 0.1 MPa to about 0.6 MPa. The second adhesive portion 512 may have a modulus ranging from about 0.01 MPa to about 0.04 MPa. The aforementioned moduli may refer to Young's moduli. The higher the modulus, the less deformation may occur due to external impact. In addition, a higher modulus may indicate relatively greater rigidity.

Referring to FIGS. 7A to 7C, in the state in which the second housing 220 is slid out from the first housing 210, the boundary between the first adhesive portion 511 and the second adhesive portion 512 may be positioned toward the first portion 230a in a horizontal direction relative to the support member 240. For example, in the state in which the second housing 220 is slid out from the first housing 210, the boundary between the first adhesive portion 511 and the second adhesive portion 512 may be positioned in the +Y direction of FIG. 7A relative to the support member 240. The boundary between the first portion 230a and the second portion 230b may be positioned in the +Y direction of FIG. 7A relative to the support member 240.

Referring to FIGS. 7A to 7C, the boundary between the first portion 230a and the second portion 230b and the boundary between the first adhesive portion 511 and the second adhesive portion 512 may coincide, as illustrated in FIG. 7A, or may be misaligned, as illustrated in FIGS. 7B and 7C.

In the embodiment illustrated in FIG. 7A, the first adhesive portion 511 may correspond to the first portion 230a of the flexible display 230, and the second adhesive portion 512 may correspond to the second portion 230b of the flexible display 230. The boundary between the first adhesive portion 511 and the second adhesive portion 512 may coincide with the boundary between the first portion 230a and the second portion 230b of the flexible display 230 (e.g., line C-C in FIG. 7A).

In the embodiment illustrated in FIG. 7B, the second adhesive portion 512 may be disposed to correspond at least partially to both the first portion 230a and the second portion 230b of the flexible display 230. In this case, the boundary between the first adhesive portion 511 and the second adhesive portion 512 may be positioned in the +Y direction of FIG. 7B relative to the boundary between the first portion 230a and the second portion 230b of the flexible display 230 (e.g., line C-C of FIG. 7B).

In an embodiment illustrated in FIG. 7C, the first adhesive portion 511 may be disposed to correspond to at least a portion of both the first portion 230a and the second portion 230b of the flexible display 230. In this case, the boundary between the first adhesive portion 511 and the second adhesive portion 512 may be positioned in the −Y direction of FIG. 7C relative to the boundary between the first portion 230a and the second portion 230b of the flexible display 230 (e.g., line C-C of FIG. 7C).

During the sliding operation of the electronic device 200 (e.g., the sliding of the second housing 220 relative to the first housing 210 or the sliding of the first housing 210 relative to the second housing 220), an adhesive layer (e.g., the first adhesive layer 510 and/or the second adhesive layer 520) positioned between the first window layer 411 and the second window layer 412 may be stretched to accommodate the slip of the first window layer 411 and/or the second window layer 412. For example, the first adhesive layer 510 and the second adhesive layer 520 may be stretched due to stress caused by a reaction force applied to the plurality of layers of the flexible display 230 during the sliding operation of the electronic device 200. In an embodiment, the relatively rigid first adhesive portion 511 may undergo less stretching than the relatively soft second adhesive portion 512. Conversely, the relatively soft second adhesive portion 512 may undergo greater stretching than the relatively rigid first adhesive portion 511.

FIG. 8A illustrates a comparative example in which only the first adhesive layer 510 is disposed between the first window layer 411 and the second window layer 412. Referring to FIG. 8A, as the thickness (e.g., L1, the z-axis direction length in FIG. 8A) of the window layer (e.g., the second window layer 412) or the thickness of the flexible display 230 increases, in the second adhesive portion 512, the required amount of stretching to accommodate the slip of the first window layer 411 and/or the second window layer 412 during the sliding operation of the electronic device 200 may also increase. As the thickness W1 of the second window layer 412 or the thickness of the flexible display 230 increases, the strength of the flexible display 230 may increase. However, as the thickness W1 of the second window layer 412 or the thickness of the flexible display 230 increases, the reaction force of the second window layer 412 or the flexible display 230 in the second portion 230b may also increase during the sliding operation of the electronic device 200. Thus, the stress applied to the second adhesive portion 512 increases, and the degree of stretching of the second adhesive portion 512 may increase. Accordingly, the strain applied to the second adhesive portion 512 may increase. In addition, as the modulus of the first adhesive portion 511 increases, the degree of stretching of the first adhesive portion 511 during the sliding operation of the electronic device 200 may decrease. In this case, as the degree of stretching of the first adhesive portion 511 decreases, the second adhesive portion 512 may need to stretch even more to accommodate the slip of the first window layer 411 and/or the second window layer 412. Thus, as the modulus of the first adhesive portion 511 increases, the strain applied to the second adhesive portion 512 may also increase. As the strain applied to the second adhesive portion 512 increases, the likelihood of failure of the second adhesive portion 512 may increase.

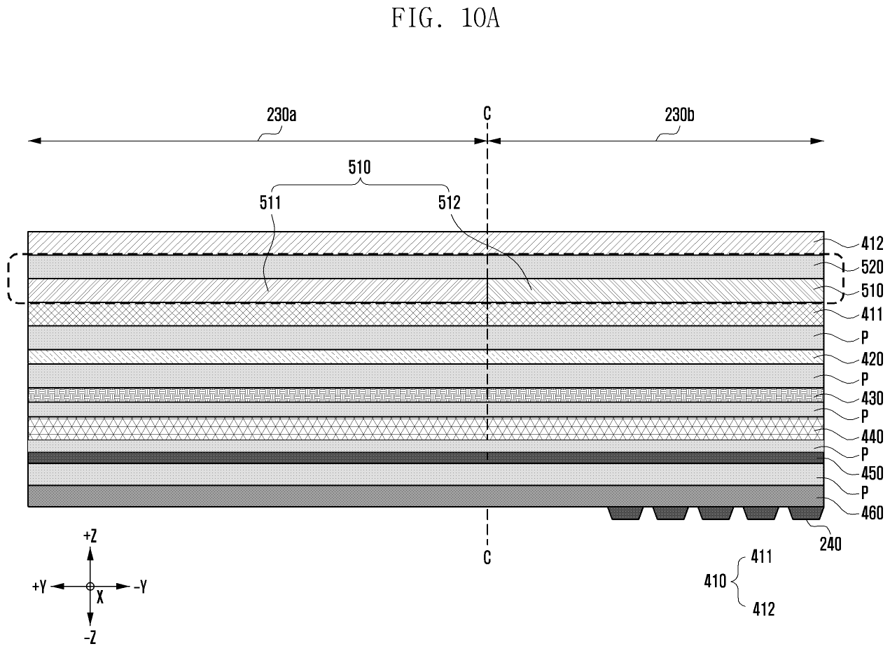

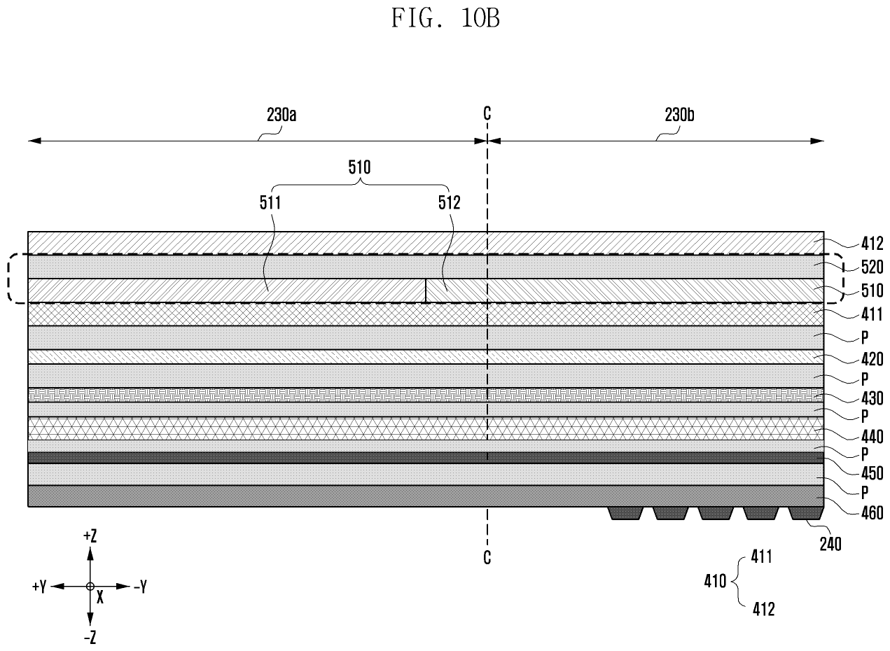

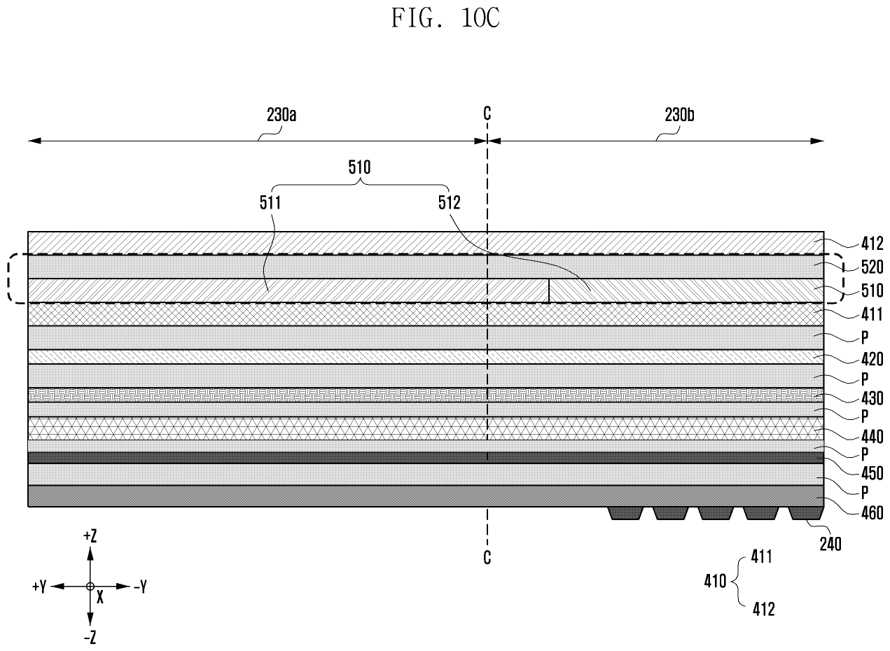

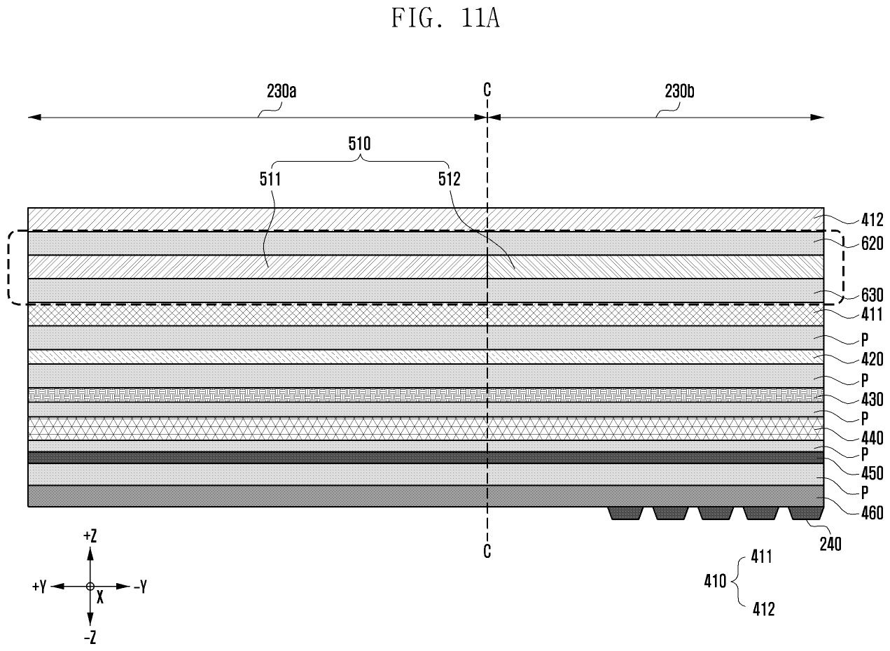

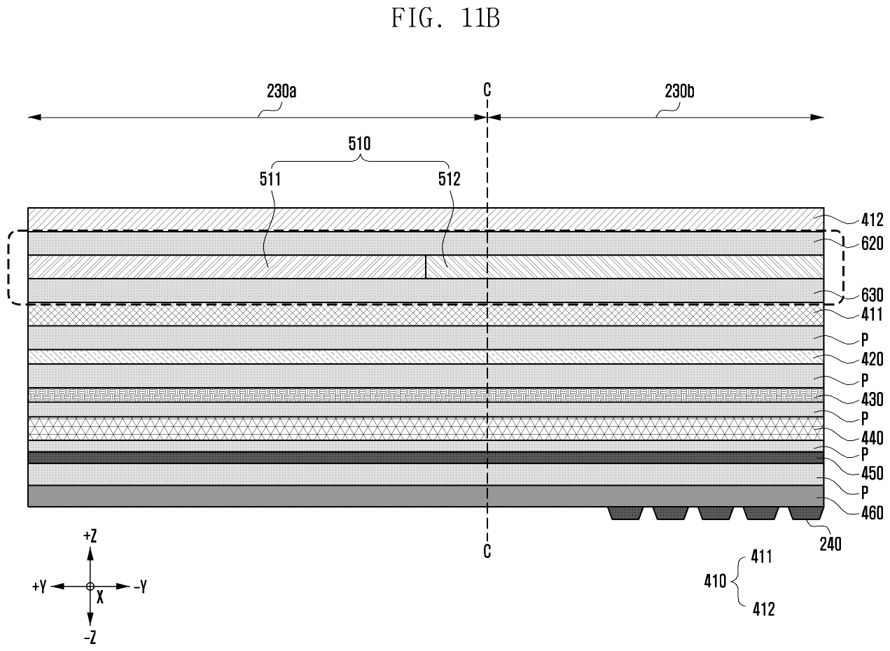

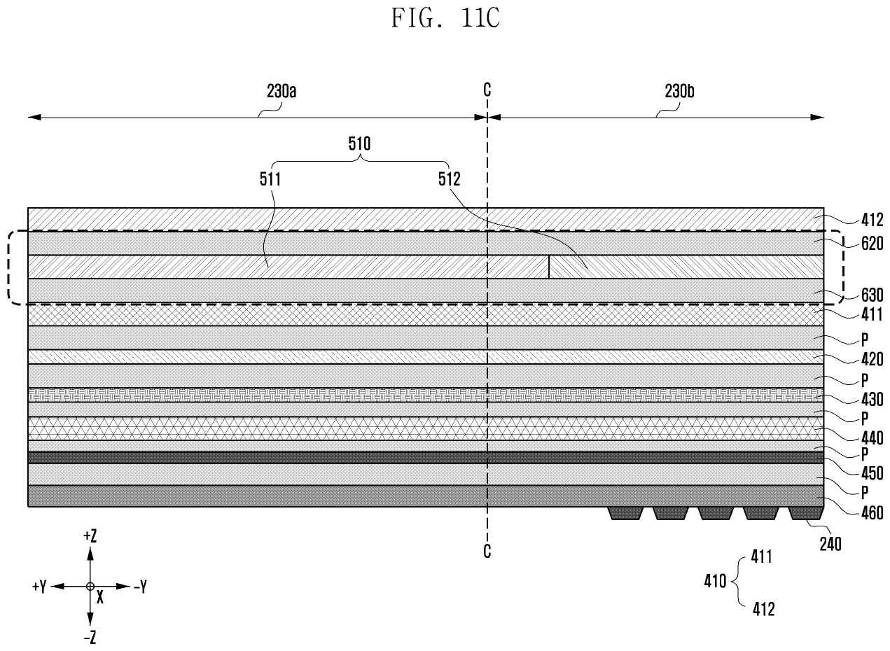

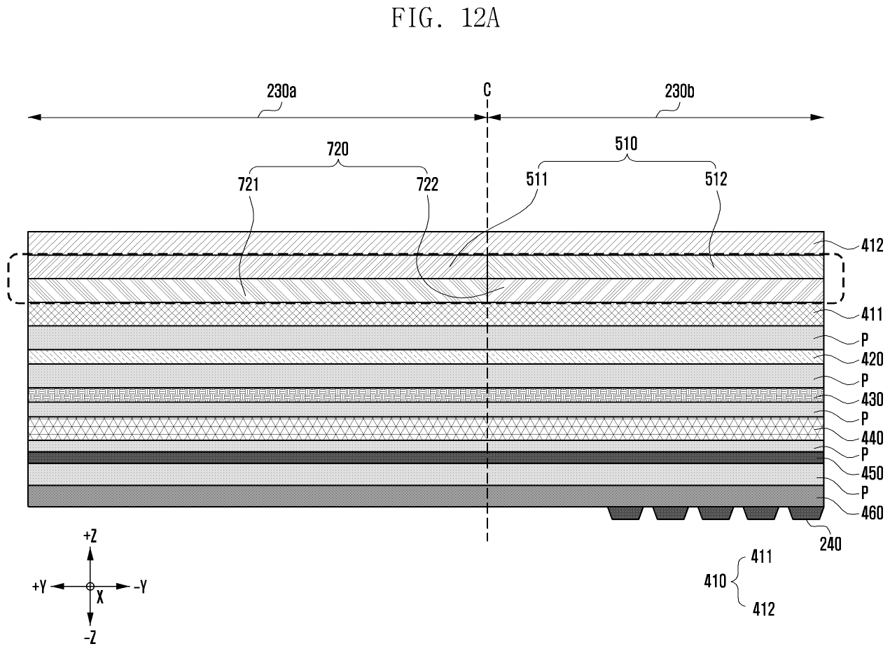

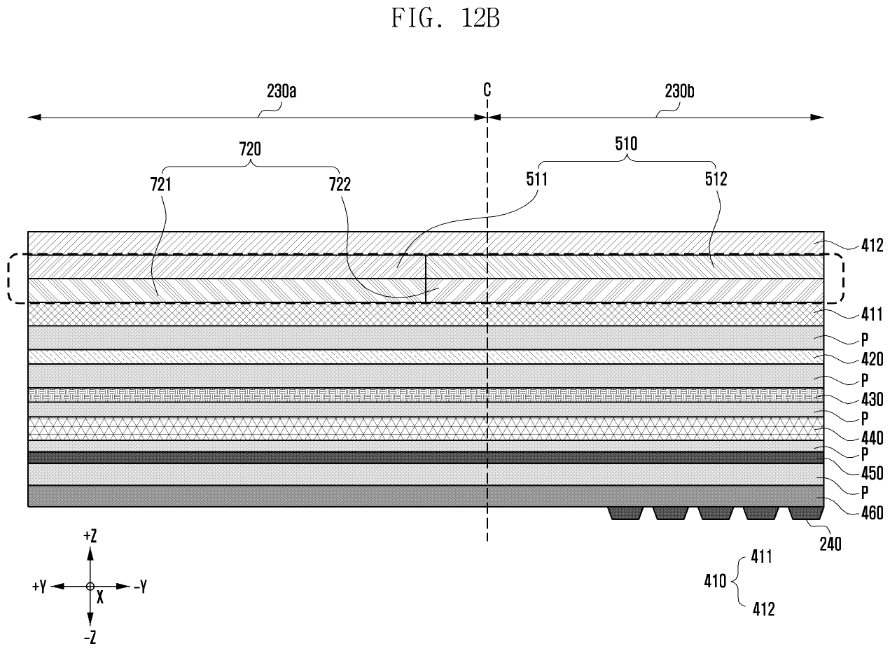

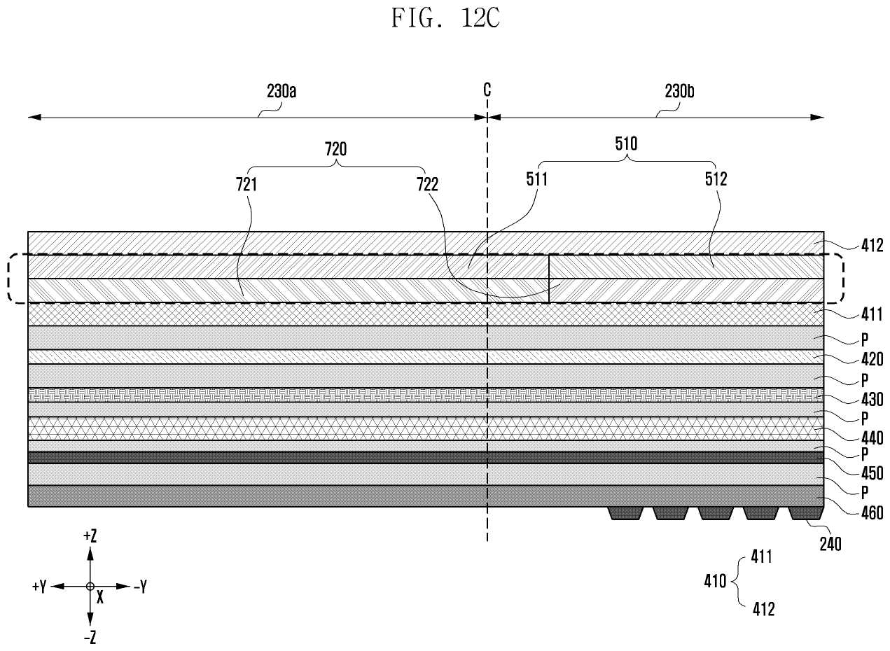

As illustrated in FIGS. 7A to 7C and 8B, the flexible display 230 may include at least two adhesive layers (e.g., the first adhesive layer 510 and the second adhesive layer 520) bonded between the first window layer 411 and the second window layer 412. In an embodiment, compared to FIG. 8A, the flexible display 230 may further include an additional adhesive layer (e.g., the second adhesive layer 520 in FIGS. 7A to 7C, the second adhesive layer 520 in FIGS. 10A to 10C, the second adhesive layer 620 in FIGS. 11A to 11C, the third adhesive layer 630 in FIGS. 11A to 11C, and/or the second adhesive layer 720 in FIGS. 12A to 12C) disposed between the first window layer 411 and the first adhesive layer 510 and/or between the second window layer 412 and the first adhesive layer 510, in addition to the first adhesive layer 510, in addition to the first adhesive layer 510. Referring to FIG. 8B, the thickness W1 of the second window layer 412 or the thickness of the flexible display 230 may be at least a certain value, and/or the modulus of the first adhesive portion 511 may be at least a certain value (e.g., at least about 0.6 MPa). In this case, an additional adhesive layer (e.g., the second adhesive layer 520 in FIGS. 7A to 7C and 8B) having a lower modulus than the first adhesive portion 511 may be disposed between the first window layer 411 and the second window layer 412 to reduce strain applied to the second adhesive portion 512.

As illustrated in FIG. 8B, the second adhesive layer 520 may be disposed between the first window layer 411 and the first adhesive layer 510. When viewed from above the flexible display 230 (e.g., in the −Z direction of FIG. 8B), the second adhesive layer 520 may correspond to the first adhesive portion 511 and the second adhesive portion 512. The second adhesive layer 520 may be bonded to the first window layer 411 and/or the first adhesive layer 510. The thickness W1 of the window layer (e.g., the first window layer 411 and/or the second window layer 412) may be at least a certain value (e.g., at least about 90 micrometers), and/or the modulus of the first adhesive portion 511 may be at least a certain value (e.g., about 0.6 MPa). In this case, the second adhesive layer 520, which has a lower modulus than the first adhesive portion 511, may be disposed between the first adhesive layer 510 and the first window layer 411 to reduce stress applied to the second adhesive portion 512. For example, the elongation rate D′1 of the second adhesive portion 512 in FIG. 8B may be observed to be lower than the elongation rate D1 of the second adhesive portion 512 in FIG. 8A. Accordingly, the likelihood of failure of the second adhesive portion 512 may be reduced.

The modulus of the second adhesive layer 520 illustrated in FIG. 8B may be equal to the modulus of the second adhesive portion 512. For example, the second adhesive layer 520 may have a modulus having a value within the range of about 0.01 MPa to about 0.04 MPa. However, the disclosure is not limited thereto, and the modulus of the second adhesive layer 520 and the modulus of the second adhesive portion 512 may be lower than the modulus of the first adhesive portion 511 but may have different values from each other. For example, the modulus of the second adhesive layer 520 may be either higher or lower than the modulus of the second adhesive portion 512.

The modulus of the first adhesive portion 511, which induces failure of the second adhesive portion 512, and/or the thickness W1 of the second window layer 412 may be variously modified.

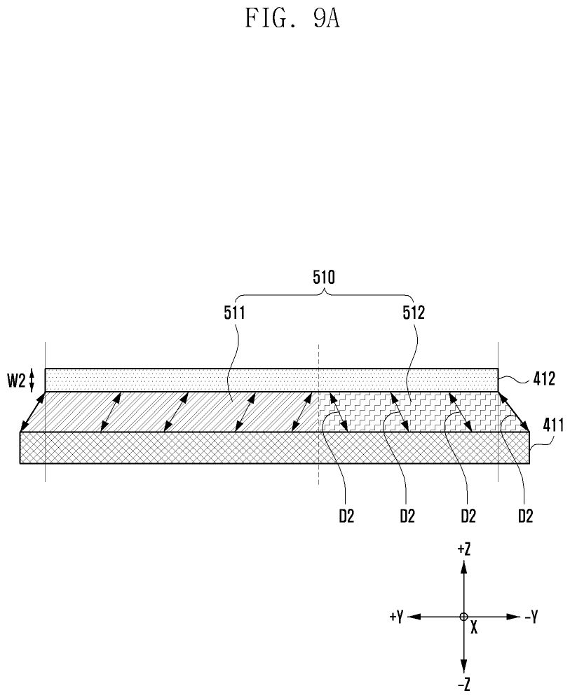

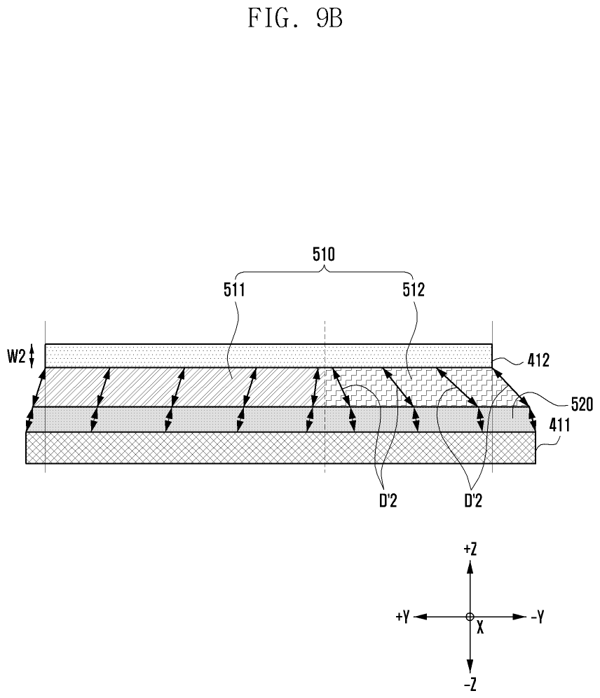

FIG. 9A is a view illustrating stress applied to the first adhesive layer disposed between the first window layer and the second window layer according to an embodiment of the disclosure.

FIG. 9B is a view illustrating stress applied to the first adhesive layer when the second adhesive layer is disposed between the first window layer and the first adhesive layer according to an embodiment of the disclosure.

In an embodiment, the thickness W2 of the second window layer 412 in FIGS. 9A and 9B may be smaller than the thickness W1 of the second window layer 412 in FIGS. 8A and 8B. For example, the thickness W2 of the second window layer 412 in FIG. 9A may be about 65 micrometers or less.

As illustrated in FIG. 9A, as the thickness W2 of the second window layer 412 or the thickness of the flexible display 230 (e.g., the z-axis direction length in FIG. 9A) decreases, the required degree of stretching of the second adhesive portion 512 to accommodate the slip of the first window layer 411 and/or the second window layer 412 during the sliding operation of the electronic device 200 may also decrease, thereby reducing the likelihood of failure. In addition, as the modulus of the first adhesive portion 511 decreases, the required degree of stretching of the second adhesive portion 512 to accommodate the slip of the first window layer 411 and/or the second window layer 412 during the sliding operation of the electronic device 200 may also decrease, thereby reducing the likelihood of failure. However, as the thickness W2 of the second window layer 412 or the thickness of the flexible display 230 decreases, or as the modulus of the first adhesive portion 511 decreases, the strength of the first portion 230a of the flexible display 230 may also decrease. Thus, the durability of the flexible display 230 may be reduced.

As illustrated in FIGS. 9A and 9B, when the thickness W2 of the second window layer 412 may be a certain value or less (e.g., about 65 micrometers or less) and/or the modulus of the first adhesive portion 511 is at most a certain value or less (e.g., about 0.1 MPa or less). In this case, an additional adhesive layer (e.g., the second adhesive layer 520 in FIGS. 7A to 7C, the second adhesive layer 520 in FIGS. 10A to 10C, the second adhesive layer 620 in FIGS. 11A to 11C, the third adhesive layer 630 in FIGS. 11A to 11C, and/or the second adhesive layer 720 in FIGS. 12A to 12C) may be disposed between the first window layer 411 and the second window layer 412. The additional adhesive layer may have a higher modulus than the second adhesive portion 512 to enhance the durability of the flexible display 230.

As illustrated in FIG. 9B, the second adhesive layer 520 may be disposed between the first window layer 411 and the first adhesive layer 510. When viewed from above the flexible display 230 (e.g., in the −Z direction of FIG. 9B), the second adhesive layer 520 may correspond to the first adhesive portion 511 and the second adhesive portion 512. The second adhesive layer 520 may be bonded to the first window layer 411 and/or the first adhesive layer 510. The thickness W2 of the second window layer 412 may be a certain value or less (e.g., about 65 micrometers or less), and/or the modulus of the first adhesive portion 511 may be a certain threshold or less (e.g., about 0.1 MPa or less). In this case, the second adhesive layer 520 may have a higher modulus than the second adhesive portion 512 and may be additionally disposed between the first window layer 411 and the first adhesive layer 510 to increase the strength of the flexible display 230.

As illustrated in FIG. 9B, the elongation rate D′2 of the second adhesive portion 512 may increase compared to the elongation rate D2 of the second adhesive portion 512 in FIG. 9A, due to the disposition of the second adhesive layer 520, which has a higher modulus than the second adhesive portion 512, between the first adhesive layer 510 and the first window layer 411. For example, as the degree of stretching of the first adhesive portion 511 is reduced due to the second adhesive layer 520, the second adhesive portion 512 of the first adhesive layer 510 may be required to stretch even more to accommodate the slip of the first window layer 411 and/or the second window layer 412. Accordingly, during the sliding operation of the electronic device 200, the flexible display 230 may accommodate slip occurring in multiple layers (e.g., the first window layer 411 and/or the second window layer 412).

The modulus of the second adhesive layer 520 illustrated in FIG. 9B may be substantially equal to the modulus of the first adhesive portion 511. For example, the second adhesive layer 520 may have a modulus having a value within a range of about 0.1 MPa to about 0.6 MPa. However, the disclosure is not limited thereto, and the modulus of the first adhesive layer 510 and the modulus of the first adhesive portion 511 may be higher than the modulus of the second adhesive portion 512 but may have different values from each other.

The modulus of the first adhesive portion 511, which reduces the durability of the flexible display 230, and/or the thickness W2 of the second window layer 412 may be variously modified.

FIGS. 10A, 10B, and 10C are views illustrating in which the second adhesive layer is disposed between the second window layer and the first adhesive layer according to various embodiments of the disclosure.

FIGS. 10A to 10C illustrate an example in which the second adhesive layer 520 is disposed between the second window layer 412 and the first adhesive layer 510, compared to FIGS. 8B and 9B described above. The function of the second adhesive layer 520 described with reference to FIGS. 8A to 9B may be substantially the same as in the embodiment of FIGS. 10A, 10B and 10C.

Referring to FIGS. 10A to 10C, the second adhesive layer 520 may correspond to the first adhesive portion 511 and the second adhesive portion 512 when viewed from above the flexible display 230 (e.g., in the −Z direction of FIG. 10A). The second adhesive layer 520 may be bonded to the second window layer 412 and/or the first adhesive layer 510. In an embodiment, the thickness of the second window layer 412 may be at least a certain value (e.g., about 90 micrometers or more), and/or the modulus of the first adhesive portion 511 may be at least a certain value (e.g., about 0.6 MPa or higher). In this case, the second adhesive layer 520 may have a lower modulus than the first adhesive portion 511 and may be disposed between the first adhesive layer 510 and the second window layer 412 to reduce stress applied to the second adhesive portion 512. Accordingly, the likelihood of failure of the second adhesive portion 512 may be reduced.

Referring to FIGS. 10A to 10C, the thickness of the second window layer 412 may be a certain value or less (e.g., about 65 micrometers or less), and/or the modulus of the first adhesive portion 511 may be a certain value or lower (e.g., about 0.1 MPa or lower). In this case, the second adhesive layer 520 may have a higher modulus than the second adhesive portion 512 and may be disposed between the second window layer 412 and the first adhesive layer 510 to increase the strength of the flexible display 230.

Referring to FIGS. 10A to 10C, in the state in which the second housing 220 is slid out from the first housing 210, the boundary between the first adhesive portion 511 and the second adhesive portion 512 may be positioned toward the first portion 230a in a horizontal direction relative to the support member 240. For example, in the state in which the second housing 220 is slid out from the first housing 210, the boundary between the first adhesive portion 511 and the second adhesive portion 512 may be positioned in the +Y direction of FIG. 10A relative to the support member 240. In The boundary between the first portion 230a and the second portion 230b may be positioned in the +Y direction of FIG. 10A relative to the support member 240.

Referring to FIG. 10A, the first adhesive portion 511 may correspond to the first portion 230a of the flexible display 230, and the second adhesive portion 512 may correspond to the second portion 230b of the flexible display. In an embodiment, the boundary between the first adhesive portion 511 and the second adhesive portion 512 may coincide with the boundary between the first portion 230a and the second portion 230b of the flexible display 230 (e.g., line C-C in FIG. 10A).

Referring to FIG. 10B, the second adhesive portion 512 may be disposed to correspond at least partially to both the first portion 230a and the second portion 230b of the flexible display 230. In this case, the boundary between the first adhesive portion 511 and the second adhesive portion 512 may be positioned in the +Y direction of FIG. 10B relative to the boundary between the first portion 230a and the second portion 230b of the flexible display 230 (e.g., line C-C of FIG. 10B).

Referring to FIG. 10C, the first adhesive portion 511 may be disposed to correspond to at least a portion of both the first portion 230a and the second portion 230b of the flexible display 230. In this case, the boundary between the first adhesive portion 511 and the second adhesive portion 512 may be positioned in the −Y direction of FIG. 10C relative to the boundary between the first portion 230a and the second portion 230b of the flexible display 230 (e.g., line C-C of FIG. 10C).

FIGS. 11A, 11B, and 11C are view illustrating a laminated state in which a second adhesive layer, a first adhesive layer, and a third adhesive layer are laminated according to various embodiments of the disclosure.

Referring to FIGS. 11A to 11C, a flexible display 230 may include a second adhesive layer 620 disposed between the second window layer 412 and the first adhesive layer 510, and a third adhesive layer 630 (e.g., the second adhesive layer 520 in FIG. 7A) disposed between the first window layer 411 and the first adhesive layer 510. The second adhesive layer 620 may be disposed and/or bonded to a first surface of the first adhesive layer 510, which faces the second window layer 412. The third adhesive layer 630 may be disposed and/or bonded to a second surface of the first adhesive layer 510, opposite to the first surface, and facing the first window layer 411. When viewed from above the flexible display 230 (e.g., in the −Z direction of FIG. 11B), the second adhesive layer 620 may correspond to the first adhesive portion 511 and the second adhesive portion 512. The second adhesive layer 620 may be bonded to the second window layer 412 and/or the first adhesive layer 510. When viewed from above the flexible display 230 (e.g., in the −Z direction of FIG. 11A), the third adhesive layer 630 may correspond to the first adhesive portion 511 and the second adhesive portion 512. In an embodiment, the third adhesive layer 630 may be bonded to the first window layer 411 and/or the first adhesive layer 510.

The function of the second adhesive layer 520 in the embodiments illustrated in FIGS. 8A, 8B, 9A, 9B, and 10A to 10C may be substantially the same as that of the second adhesive layer 620 and/or the third adhesive layer 630 in the embodiments illustrated in FIGS. 11A to 11C.

Referring to FIGS. 11A to 11C, the thickness of the second window layer 412 may be at least a certain value (e.g., about 90 micrometers or more), and/or the modulus of the first adhesive portion 511 may be at least a certain value (e.g., about 0.6 MPa or higher). In this case, the second adhesive layer 620 may have a lower modulus than the first adhesive portion 511 and may be disposed between the first adhesive layer 510 and the second window layer 412 to reduce stress applied to the second adhesive portion 512 during the sliding operation of the electronic device 200. In addition, the third adhesive layer 630 may have a lower modulus than the first adhesive portion 511 and may be disposed between the first adhesive layer 510 and the first window layer 411 to reduce stress applied to the second adhesive portion 512 during the sliding operation of the electronic device 200. The second adhesive layer 620 and the third adhesive layer 630 may have a modulus equal to, higher than, or lower than the second adhesive portion 512. The second adhesive layer 620 and the third adhesive layer 630 may have moduli that are equal to or different from each other.

Referring to FIGS. 11A to 11C, the thickness of the second window layer 412 may be a certain value or less (e.g., about 65 micrometers or less), and/or the modulus of the first adhesive portion 511 may be a certain value or lower (e.g., about 0.1 MPa or lower). In this case, the second adhesive layer 620 may have a higher modulus than the second adhesive portion 512 and may be disposed between the second window layer 412 and the first adhesive layer 510 to increase the strength of the flexible display 230. In addition, the third adhesive layer 630 may have a higher modulus than the second adhesive portion 512 and may be disposed between the first window layer 411 and the first adhesive layer 510 to increase the strength of the flexible display 230. At least one of the second adhesive layer 620 and the third adhesive layer 630 may have a modulus equal to or lower than the modulus of the first adhesive portion 511. The second adhesive layer 620 and the third adhesive layer 630 may have moduli that are equal to or different from each other.

The second adhesive layer 620 and the third adhesive layer 630 may be configured to have a modulus that reduces the likelihood of failure of the second adhesive portion 512 and enhances the durability of the flexible display 230. For example, the second adhesive layer 620 may have a lower modulus than the first adhesive portion 511 and/or the third adhesive layer 630 to reduce stress applied to the second adhesive portion 512 during the sliding operation of the electronic device 200. Conversely, the third adhesive layer 630 may have a higher modulus than the second adhesive layer 620 to enhance the durability of the flexible display 230. In an embodiment, the third adhesive layer 630 may have a higher modulus than the second adhesive portion 512.

According to another embodiment of the disclosure, the second adhesive layer 620 may have a higher modulus than the third adhesive layer 630 and/or the second adhesive portion 512 to enhance the durability of the flexible display 230. In this case, the third adhesive layer 630 may have a lower modulus than the first adhesive portion 511 and/or the second adhesive layer 620 to reduce the likelihood of failure of the second adhesive portion 512.

Referring to FIGS. 11A to 11C, in the state in which the second housing 220 is slid out from the first housing 210, the boundary between the first adhesive portion 511 and the second adhesive portion 512 may be positioned toward the first portion 230a in a horizontal direction relative to the support member 240. For example, in state in which the second housing 220 is slid out from the first housing 210, the boundary between the first adhesive portion 511 and the second adhesive portion 512 may be positioned in the +Y direction of FIG. 11A relative to the support member 240. The boundary between the first portion 230a and the second portion 230b may be positioned in the +Y direction of FIG. 11A relative to the support member 240.

Referring to FIG. 11A, the first adhesive portion 511 may correspond to the first portion 230a of the flexible display 230, and the second adhesive portion 512 may correspond to the second portion 230b of the flexible display 230. The boundary between the first adhesive portion 511 and the second adhesive portion 512 may coincide with the boundary between the first portion 230a and the second portion 230b of the flexible display 230 (e.g., line C-C in FIG. 11A).

Referring to FIG. 11B, the second adhesive portion 512 may be disposed to correspond at least partially to both the first portion 230a and the second portion 230b of the flexible display 230. In this case, the boundary between the first adhesive portion 511 and the second adhesive portion 512 may be positioned in the +Y direction of FIG. 11B relative to the boundary between the first portion 230a and the second portion 230b of the flexible display 230 (e.g., line C-C of FIG. 11B).

Referring to FIG. 11C, the first adhesive portion 511 may be disposed to correspond to at least a portion of both the first portion 230a and the second portion 230b of the flexible display 230. In this case, the boundary between the first adhesive portion 511 and the second adhesive portion 512 may be positioned in the −Y direction of FIG. 11C relative to the boundary between the first portion 230a and the second portion 230b of the flexible display 230 (e.g., line C-C of FIG. 11C).

FIGS. 12A, 12B, and 12C are views illustrating an embodiment in which a second adhesive layer disposed between the first adhesive layer and the first window layer includes a plurality of adhesive members having different moduli, according to various embodiments of the disclosure.

Referring to FIGS. 12A to 12C, the flexible display 230 may include a second adhesive layer 720 (e.g., the second adhesive layer 520 in FIG. 7A) disposed between the first adhesive layer 510 and the first window layer 411. When viewed from above the flexible display 230 (e.g., in the −Z direction of FIG. 12A), the second adhesive layer 720 may include a third adhesive portion 721 corresponding at least partially to the first portion 230a of the flexible display 230 and a fourth adhesive portion 722 corresponding at least partially to both the first portion 230a and the second portion 230b of the flexible display 230. In an embodiment, when viewed from above the flexible display 230, at least a portion of the third adhesive portion 721 may overlap the first adhesive portion 511. In addition, at least a portion of the fourth adhesive portion 722 may overlap the second adhesive portion 512. The third adhesive portion 721 and the fourth adhesive portion 722 may be separate configurations, but may be integrated as a single configuration. The third adhesive portion 721 may be made of a rigid material to provide a certain level of strength to the first portion 230a of the flexible display 230, which is always exposed to the outside. For example, the third adhesive portion 721 may have a relatively lower modulus than the fourth adhesive portion 722. The fourth adhesive portion 722 may be made of a relatively softer material than the third adhesive portion 721 to accommodate the slip of the first window layer 411 and/or the second window layer 412 occurring in the second portion 230b of the flexible display 230 during the slide-in or slide-out operation of the electronic device 200.

Referring to FIGS. 12A to 12C, the boundary between the third adhesive portion 721 and the fourth adhesive portion 722 may be positioned toward the first portion 230a in a horizontal direction relative to the support member 240. For example, in the state in which the second housing 220 is slid out from the first housing 210, the boundary between the third adhesive portion 721 and the fourth adhesive portion 722 may be positioned in the +Y direction of FIG. 12A relative to the support member 240. The boundary between the first portion 230a and the second portion 230b may be positioned in the +Y direction of FIG. 12A relative to the support member 240.

Referring to FIGS. 12A to 12C, the third adhesive portion 721 and the fourth adhesive portion 722 may correspond to the first adhesive portion 511 and the second adhesive portion 512, respectively.

Referring to FIG. 12A, the third adhesive portion 721 may correspond to the first portion 230a of the flexible display 230, and the fourth adhesive portion 722 may correspond to the second portion 230b of the flexible display 230. The boundary between the third adhesive portion 721 and the fourth adhesive portion 722 may coincide with the boundary between the first portion 230a and the second portion 230b of the flexible display 230 (e.g., line C-C in FIG. 12A).

Referring to FIG. 12B, the second adhesive portion 512 may be disposed to correspond at least partially to both the first portion 230a and the second portion 230b of the flexible display 230. Since the fourth adhesive portion 722 corresponds to the second adhesive portion 512, the fourth adhesive portion may be disposed to correspond at least partially to both the first portion 230a and the second portion 230b of the flexible display 230. In this case, the boundary between the third adhesive portion 721 and the fourth adhesive portion 722 may be positioned in the +Y direction of FIG. 12B relative to the boundary between the first portion 230a and the second portion 230b of the flexible display 230 (e.g., line C-C of FIG. 12B).

Referring to FIG. 12C, the first adhesive portion 511 may be disposed to correspond to at least a portion of both the first portion 230a and the second portion 230b of the flexible display 230. Since the third adhesive portion 721 corresponds to the first adhesive portion 511, the third adhesive portion may be disposed to partially correspond to both the first portion 230a and the second portion 230b of the flexible display 230. In this case, the boundary between the third adhesive portion 721 and the fourth adhesive portion 722 may be positioned in the −Y direction of FIG. 12C relative to the boundary between the first portion 230a and the second portion 230b of the flexible display 230 (e.g., line C-C of FIG. 12C).

Referring to FIGS. 12A to 12C, when the thickness of the second window layer 412 is at least a certain value (e.g., about 90 micrometers or more) and/or the modulus of the first adhesive portion 511 is at least a certain value, at least one of the third adhesive portion 721 and the fourth adhesive portion 722 may have a lower modulus than the first adhesive portion 511 and may be disposed between the first adhesive layer 510 and the second window layer 412 to reduce stress applied to the second adhesive portion 512. For example, at least one of the third adhesive portion 721 and the fourth adhesive portion 722 of the second adhesive layer 720 may have a lower modulus than the first adhesive portion 511 to reduce stress applied to the second adhesive portion 512.

Referring to FIGS. 12A to 12C, when the thickness of the window layer (e.g., the first window layer 411 and/or the second window layer 412) is a certain value or less (e.g., about 65 micrometers or less) and/or the modulus of the first adhesive portion 511 is a certain value or lower, at least one of the third adhesive portion 721 and the fourth adhesive portion 722 may have a higher modulus than the second adhesive portion 512 and may be disposed between the second window layer 412 and the first adhesive layer 510 to increase the strength of the flexible display 230. For example, at least one of the third adhesive portion 721 and the fourth adhesive portion 722 of the second adhesive layer 720 may have a higher modulus than the second adhesive portion 512 to increase the strength of the flexible display 230.

According to an embodiment of the disclosure, an additional adhesive layer (e.g., the second adhesive layer 520 in FIGS. 7A to 7C, the second adhesive layer 520 in FIGS. 10A to 10C, the second adhesive layer 620 in FIGS. 11A to 11C, the third adhesive layer 630 in FIGS. 11A to 11C, and/or the second adhesive layer 720 in FIGS. 12A to 12C) may be disposed between the first window layer 411 and the second window layer 412, in addition to the first adhesive layer 510. The additional adhesive layer may enhance the durability of the flexible display or reduce the likelihood of failure of an adhesive member (e.g., the second adhesive portion 512) positioned in the second portion of the flexible display.

In the foregoing description, the numerical values for the moduli of the first adhesive layer 510, the second adhesive layers 520, 620, and 720, the third adhesive layer 730, and/or the thickness of the second window layer 412 have been provided by way of example and are not necessarily limited thereto. The numerical values for the moduli of the first adhesive layer 510, the second adhesive layers 520 and 620, and the third adhesive layer, and/or the thickness of the second window layer 412 may be variously modified within a range capable of being implemented by a person ordinarily skilled in the art.

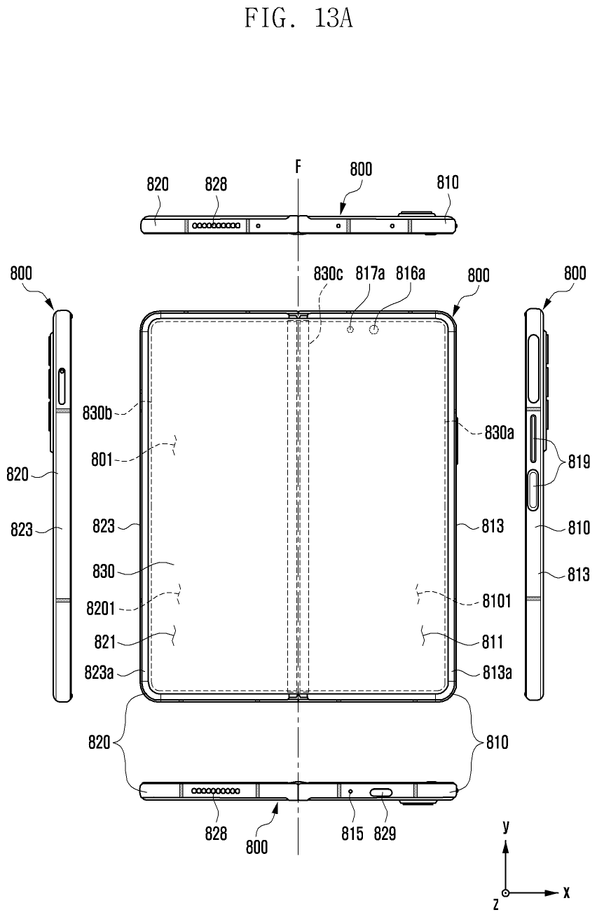

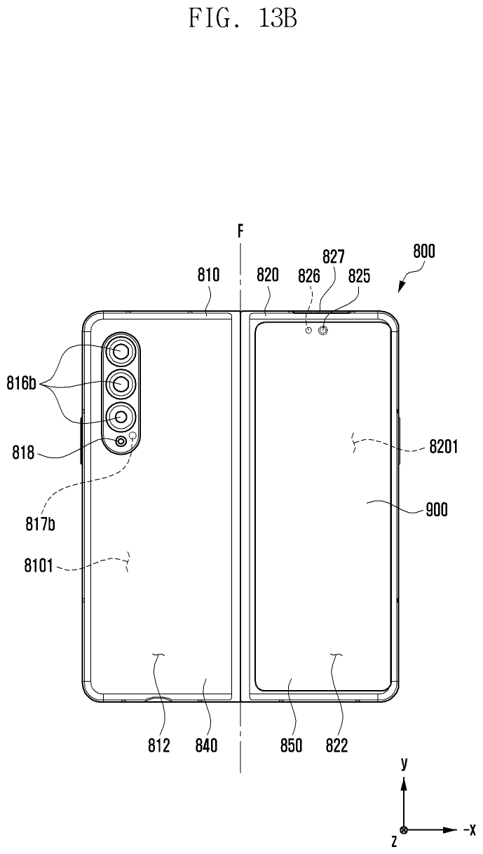

FIGS. 13A and 13B are a front view and a rear view of an electronic device in an unfolded state according to various embodiments of the disclosure.

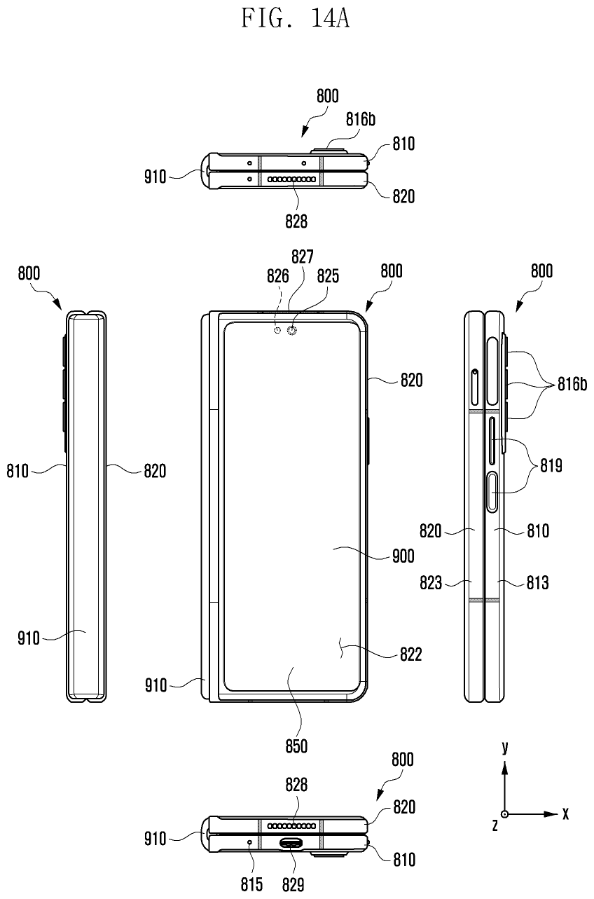

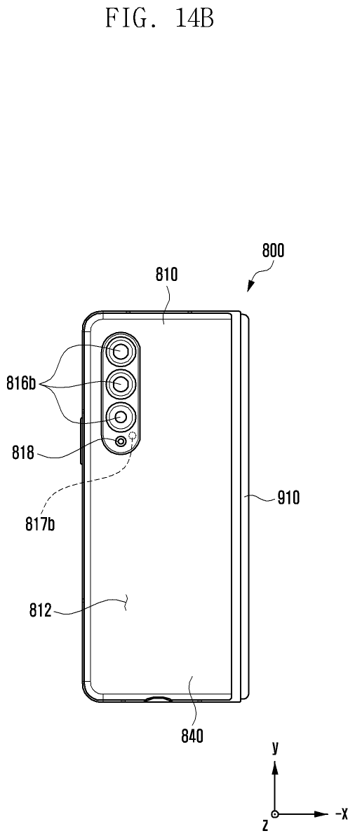

FIGS. 14A and 14B are a front view and a rear view of the electronic device in a folded state according to various embodiments of the disclosure.

The electronic device 800 illustrated in FIGS. 13A, 13B, 14A, and 14B may be a foldable electronic device in which a plurality of housings 810 and 820 are configured to fold or unfold via a hinge device. The electronic device 800 may include the flexible display 230 described with reference to FIGS. 6, 7A to 7C, 8A, 8B, 9A, 9B, 10A to 10C, 11A to 11C, and 12A to 12C. For example, the electronic device 800 of FIGS. 13A, 13B, 14A, and 14B may include at least one of the first adhesive layer 510 of the flexible display 230 described with reference to FIGS. 6, 7A to 7C, 8A, 8B, 9A, 9B, 10A to 10C, 11A to 11C, and 12A to 12C, the second adhesive layer 520 of FIGS. 7A to 7C, the second adhesive layer 520 of FIGS. 10A to 10C, the second adhesive layer 620 of FIGS. 11A to 11C, the third adhesive layer 630 of FIGS. 11A to 11C, and/or the second adhesive layer 720 described with reference to FIGS. 12A to 12C.

Referring to FIGS. 13A, 13B, 14A, and 14B, the first display 830 (e.g., a flexible display) may include the flexible display 230 of FIGS. 6 to 12C described above. The first display 830 may include the window layer 410 of FIG. 6, a polarizer (POL) 420 (e.g., a polarizing film) disposed on the rear surface of the window layer 410, a display panel 430, a polymer layer 440, at least one functional layer 450, and a support plate 460.

At least two adhesive layers (e.g., the first adhesive layer 510) may be disposed between the first window layer 411 and the second window layer 412. The first window layer 411 and the second window layer 412 may be attached to each other through adhesive layers (e.g., the first adhesive layer 510 and the second adhesive layer 520). When viewed from above the first display 830 (e.g., in the Z direction of FIG. 13A), the first adhesive portion 511 of the first adhesive layer 510 may correspond at least partially to at least a portion of each of the first area 830a and the second area 830b of the first display 830. In an embodiment, the second adhesive portion 512 of the first adhesive layer 510 may correspond to the folding area 830c of the first display 830. At least a portion of the second adhesive portion 512 may extend from the folding area 830c to the first area 830a and the second area 830b. For example, when viewed from above the first display 830, the second adhesive portion 512 may be disposed in the folding area 830c and may at least partially extend into the first area 830a and the second area 830b. The first adhesive portion 511 may be made of a relatively rigid material to provide a certain level of strength to the first area 830a and the second area 830b, which are substantially planar areas. The second adhesive portion 512 may be made of a relatively softer material than the first adhesive portion 511 to reduce the intensity of the reaction force generated in the folding area 830c during the folding operation of the electronic device 800.

An additional adhesive layer (e.g., the second adhesive layer 520 in FIGS. 7A to 7C, the second adhesive layer 520 in FIGS. 10A to 10C, the second adhesive layer 620 in FIGS. 11A to 11C, the third adhesive layer 630 in FIGS. 11A to 11C, and/or the second adhesive layer 720 in FIGS. 12A to 12C) may be disposed between the first window layer 411 and the second window layer 412, in addition to the first adhesive layer 510. The additional adhesive layer may enhance the durability of the first display 830 or reduce the likelihood of failure of an adhesive member (e.g., the second adhesive portion 512) positioned in the folding area 830c of the first display 830.

Referring to FIGS. 13A, 13B, 14A, and 14B, the electronic device 800 may include a pair of housings 810 and 820 (e.g., a foldable housing structure) that are rotatably coupled via at least one hinge device (e.g., a hinge module, a hinge assembly, or a hinge structure) to be foldable relative to each other about a folding axis F, a first display 830 (e.g., a flexible display, a foldable display, or a main display) disposed across the pair of housings 810 and 820, and/or a second display 900 (e.g., a sub-display) disposed via the second housing 820. At least a portion of the at least one hinge device may be disposed to be invisible from the outside through the first housing 810 and the second housing 820, and in the unfolded state, the hinge housing 910 (e.g., a hinge cover), which covers the foldable portion, may be disposed to be invisible from the outside. Herein, the surface on which the first display 830 is disposed may be defined as the front surface of the electronic device 800, and the surface opposite to the front surface may be defined as the rear surface of the electronic device 800. In addition, the surface surrounding the space between the front surface and the rear surface may be defined as the side surface of the electronic device 800.

The pair of housings 810 and 820 may include a first housing 810 and a second housing 820 that are foldable relative to each other via at least one hinge device. The pair of housings 810 and 820 are not limited to the shape and assembly illustrated in FIGS. 13A, 13B, 14A, and 14B, but may be implemented by other shapes or other combinations and/or assemblies of components. The first housing 810 and the second housing 820 may be disposed on opposite sides of the folding axis F, may have shapes that are generally symmetrical to each other with respect to the folding axis F, and may be folded to match each other. According to some embodiments of the disclosure, the first housing 810 and the second housing 820 may be folded asymmetrically with respect to the folding axis F. The first housing 810 and the second housing 820 may form an angle or have a distance therebetween, which may vary depending on whether the electronic device 200 is in the unfolded state, in the folded state, or in the intermediate state.

In the unfolded state of the electronic device 800, the first housing 810 may be connected to at least one hinge device and may include a first surface 811 disposed to face the front of the electronic device 800, a second surface 812 oriented in the opposite direction of the first surface 811, and/or a first side surface member 813 surrounding at least a portion of a first space 8101 between the first surface 811 and the second surface 812. In the unfolded state of the electronic device 800, the second housing 820 may include a third surface 821 connected to the at least one hinge device and disposed to face the front of the electronic device 800, a fourth surface 822 facing away from the third surface 821, and/or a second side surface member 823 surrounding at least a portion of a second space 8201 between the third surface 821 and the fourth surface 822. The first surface 811 may be oriented in substantially the same direction as the third surface 821 in the unfolded state and may at least partially face the third surface 821 in the folded state. The electronic device 800 may include a recess 801 provided to accommodate the first display 830 through structural coupling of the first housing 810 and the second housing 820. In an embodiment, the recess 801 may have substantially the same size as the first display 830. The first housing 810 may include a first protection frame 813a (e.g., a first decoration member) which is coupled to the first side surface member 813 and disposed to overlap the edges of the first display 830 when the first display 830 is viewed from above, thereby covering the edges of the first display 830 to be invisible from the outside. The first protection frame 813a may be integrated with the first side surface member 813. The second housing 820 may include a second protection frame 823a (e.g., a second decoration member) which is coupled to the second side surface member 823 and disposed to overlap the edges of the first display 830 when the first display 830 is viewed from above, thereby covering the edges of the first display 830 to be invisible from the outside. The second protection frame 823a may be integrated with the second side surface member 823. In some embodiments, the first protection frame 813a and the second protection frame 823a may be omitted.

The hinge housing 910 (e.g., a hinge cover) may be disposed between the first housing 810 and the second housing 820 and may be disposed to cover a portion of the at least one hinge device (e.g., at least one hinge module). The hinge housing 910 may be covered by a portion of the first housing 810 and the second housing 820 or exposed to the outside, depending on whether the electronic device 800 is in the unfolded state, the folded state, or the intermediate state. For example, when the electronic device 800 is in the unfolded state, at least a portion of the hinge housing 910 may be disposed to be covered by the first housing 810 and the second housing 820 to be substantially invisible from the outside. When the electronic device 800 is in the folded state, at least a portion of the hinge housing 910 may be disposed between the first housing 810 and the second housing 820 to be visible from the outside. When the electronic device is in the intermediate state in which the first housing 810 and the second housing 820 are folded with a certain angle, the hinge housing 910 may be disposed between the first housing 810 and the second housing 820 to be at least partially visible from the outside of the electronic device 800. For example, the area of the hinge housing 910 exposed to the outside may be smaller than that in the case where the electronic device is fully folded. The hinge housing 910 may include a curved surface.

According to an embodiment of the disclosure, when the electronic device 800 is in the unfolded state (e.g., the state in FIGS. 13A and 13B), the first housing 810 and the second housing 820 form an angle of about 180 degrees therebetween, and the first area 830a, the second area 830b, and the folding area 830c of the first display 830 may be arranged to be oriented in substantially the same direction (e.g., the z-axis direction) while substantially forming the same plane. According to another embodiment of the disclosure, when the electronic device 800 is in the unfolded state, the first housing 810 may rotate by an angle of about 360 degrees with respect to the second housing 820 to be folded in the opposite direction such that the second surface 812 and the fourth surface 822 face each other (out-folding type).

When the electronic device 800 is in the folded state (e.g., the state in FIGS. 14A and 14B), the first surface 811 of the first housing 810 and the third surface 821 of the second housing 820 may be disposed to face each other. In this case, the first area 830a and the second area 830b of the first display 830 may form a narrow angle (e.g., in the range of 0 degrees to about 10 degrees) with respect to each other via the folding area 830c, and may be disposed to face each other. At least a portion of the folding area 830c may be transformed into a curved shape with a predetermined curvature. When the electronic device 800 is in the intermediate state, the first housing 810 and the second housing 820 may be disposed to form a certain angle therebetween. In this case, the first area 830a and the second area 830b of the first display 830 may form an angle that is greater than that in the folded state and smaller than that in the unfolded state, and the curvature of the folding area 830c may be smaller than that in the folded state and greater than that in the unfolded state. In some embodiments, the first housing 810 and the second housing 820 may form an angle that allows the first and second housings to stop at a predetermined folding angle between the folded state and the unfolded state via the at least one hinge device (free stop function). According to some embodiments of the disclosure, the first housing 810 and the second housing 820 may be continuously operated while being pressed in the unfolding or folding direction with reference to a predetermined inflection angle via the at least one hinge device.

The electronic device 800 may include at least one of the following components: one or more displays 830 and 900, input devices 815, sound output devices 827 and 828, sensor modules 817a, 817b, and 826, camera modules 816a, 816b, and 825, key input devices 819, indicators (not illustrated), or connector ports 829 which are disposed on or in the first housing 810 and/or the second housing 820. In some embodiments, at least one of the components may be omitted from the electronic device 800, or at least one other component may be additionally included in the electronic device 200.

The one or more displays 830 and 900 may include a first display 830 (e.g., a flexible display) disposed to be supported by the first surface 811 of the first housing 810 and the third surface 821 of the second housing 820 via the at least one hinge device, and a second display 900 disposed in the inner space of the second housing 820 to be at least partially visible from the outside through the fourth surface 822. The second display 900 may be disposed in the inner space of the first housing 810 to be visible from the outside through the second surface 812. The first display 830 may be mainly used when the electronic device 800 is in the unfolded state, and the second display 900 may be mainly used when the electronic device 800 is in the folded state. When the electronic device 800 is in the intermediate state, the electronic device 200 may control the first display 830 and/or the second display 900 to be usable based on the folding angle between the first housing 810 and the second housing 820.

The first display 830 may be placed in an accommodation space defined by the pair of housings 810 and 820. For example, the first display 830 may be disposed in the recess 801 defined by the pair of housings 810 and 820, and may be disposed to occupy substantially most of the front surface of the electronic device 200 in the unfolded state. The first display 830 may include a flexible display, at least a portion of which is transformable into a flat shape or a curved shape. The first display 830 may include a first area 830a facing the first housing 810 and a second area 830b facing the second housing 820. The first display 830 may include a folding area 830c including a portion of the first area 830a and a portion of the second area 830b with reference to the folding axis F. At least a portion of the folding area 830c may include an area corresponding to the at least one hinge device. The area division of the first display 830 is merely an physical division based on the pair of housings 810 and 820 and the at least one hinge device; in practice, the first display 830 may display a single seamless entire screen via the pair of housings 810 and 820 and the at least one hinge device. The first area 830a and the second area 830b may have an overall symmetrical shape or a partially asymmetrical shape with respect to the folding area 830c.

The electronic device 800 may include a first rear surface cover 840 disposed on the second surface 812 of the first housing 810 and a second rear surface cover 850 disposed on the fourth surface 822 of the second housing 820. In some embodiments, at least a portion of the first rear surface cover 840 may be formed integrally with the first side surface member 813. According to some embodiments of the disclosure, at least a portion of the second rear surface cover 850 may be integrated with the second side surface member 823. At least one of the first rear surface cover 840 and the second rear surface cover 850 may be made of a substantially transparent plate (e.g., a glass plate including various coating layers, or a polymer plate) or an opaque plate. The first rear surface cover 840 may be made of, for example, coated or colored glass, ceramic, polymer, metal (e.g., aluminum, stainless steel (STS), or magnesium), or an opaque plate such as a combination of two or more of these materials. The second rear surface cover 850 may be made of a substantially transparent plate of, for example, glass or polymer. Accordingly, the second display 900 may be disposed in the inner space of the second housing 820 to be visible from the outside through the second rear surface cover 850.

The input devices 815 may include a microphone. The input devices 815 may include a plurality of microphones disposed to detect the direction of sound. The sound output devices 827 and 828 may include speakers. The sound output devices 827 and 828 may include a call receiver 827 disposed through the fourth surface 822 of the second housing 820, and an external speaker 828 disposed through at least a portion of the second side surface member 823 of the second housing 820. The input devices 815, the sound output devices 827 and 828, and the connector ports 829 may be disposed in the spaces of the first housing 810 and/or the second housing 820, and may be exposed to the external environment through one or more holes provided in the first housing 810 and/or the second housing 820. The holes provided in the first housing 810 and/or the second housing 820 may be commonly used for the input device 815 and the sound output devices 827 and 828. The sound output devices 827 and 828 may include a speaker that operates without holes provided in the first housing 810 and/or the second housing 820 (e.g., a piezo speaker).

The camera modules 816a, 816b, and 825 may include a first camera module 816a disposed on the first surface 811 of the first housing 810, a second camera module 816b disposed on the second surface 812 of the first housing 810, and/or a third camera module 825 disposed on the fourth surface 822 of the second housing 820. The electronic device 800 may include a flash 818 located near the second camera module 816b. The flash 818 may include, for example, a light-emitting diode or a xenon lamp. The camera modules 816a, 816b, and 825 may each include one or more lenses, an image sensor, and/or an image signal processor. At least one of the camera modules 816a, 816b, and 825 may include two or more lenses (e.g., wide-angle and telephoto lenses) and image sensors, and the camera modules may be disposed together on one surface of the first housing 810 and/or the second housing 820.

The sensor modules 817a, 817b, and 826 may generate electrical signals or data values corresponding to an internal operating state or an external environmental state of the electronic device 800. The sensor modules 817a, 817b, and 826 may include a first sensor module 817a disposed on the first surface 811 of the first housing 810, a second sensor module 817b disposed on the second surface 812 of the first housing 810, and/or a third sensor module 826 disposed on the fourth surface 822 of the second housing 820. The sensor modules 817a, 817b, and 826 may include at least one of a gesture sensor, a grip sensor, a color sensor, an infrared (IR) sensor, an illumination sensor, an ultrasonic sensor, an iris recognition sensor, or a distance detection sensor (e.g., a time-of-flight (TOF) sensor or a light detection and ranging (LiDAR) sensor).

The electronic device 800 may further include at least one of sensor modules (not illustrated), for example, an air pressure sensor, a magnetic sensor, a biometric sensor, a temperature sensor, a humidity sensor, or a fingerprint recognition sensor. In some embodiments, the fingerprint recognition sensor may be disposed through at least one of the first side surface member 813 of the first housing 810 and/or the second side surface member 823 of the second housing 820.

The key input devices 819 may be disposed to be exposed outside through the first side surface member 813 of the first housing 810. The key input devices 819 may be disposed to be exposed outside through the second side surface member 823 of the second housing 220. According to some embodiments of the disclosure, some or all of the above-mentioned key input devices 819 may be omitted, and a key input device 819, which is not included, may be implemented in another form, such as a soft key, on at least one display 830 or 900. As another embodiment, the key input devices 819 may be implemented using pressure sensors included in at least one display 830 or 900.

The connector ports 829 may include a connector (e.g., a USB connector or an interface connector port module (IF module)) configured to transmit/receive power and/or data to/from an external electronic device. The connector ports 829 may further include a separate connector port (e.g., an ear jack hole) for performing a function to transmit/receive an audio signal together with an external electronic device or for performing a function to transmit/receive an audio signal.

One or more camera modules 816a and 825 among the camera modules 816a, 816b, and 825, one or more sensor modules 817a and 826 among the sensor modules 817a, 817b, and 826, and/or an indicator may be disposed to be exposed through one or more displays 830 and 900. For example, the at least one camera module 816a or 825, the at least one sensor module 817a or 826, and/or the indicator may be disposed in the inner space of the one or more housings 810 and 820 below the active area (display area) of the one or more displays 830 and 300, and may be disposed to come into contact with the external environment through an opening perforated up to the cover member (e.g., a window layer (not illustrated) of the first display 830 and/or the second rear surface cover 850) or a transparent area. An area in which the at least one display 830 or 900 and the at least one camera module 816a or 825 face each other may be provided as a transmission area with a predetermined transmittance as a portion of a content display area. The transmission area may have a transmittance ranging from about 5% to about 20%. The transmissive area may include an area overlapping the effective area (e.g., a view angle area) of the at least one camera module 816a or 825 through which light imaged by an image sensor to generate an image passes. For example, the transmissive area of the display 830 or 900 may include an area having a lower pixel density than the periphery. For example, the transmissive area may replace an opening. For example, the at least one camera module 816a or 825 may include an under-display camera (UDC) or an under-panel camera (UPC). According to another embodiment of the disclosure, some camera modules or sensor modules 817a and 826 may be arranged to perform the functions thereof without being visually exposed through a display. For example, the areas facing the camera modules 816a and 825 and/or the sensor modules 817a and 826 disposed under the displays 830 and 900 (e.g., a display panel) may have an under-display camera (UDC) structure, and may not require a perforated opening.

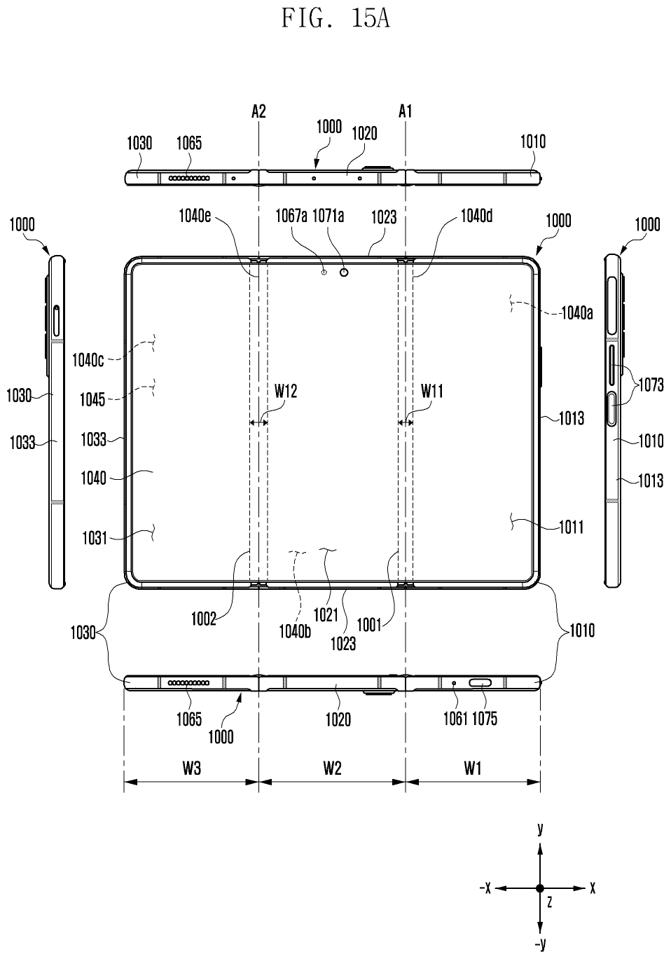

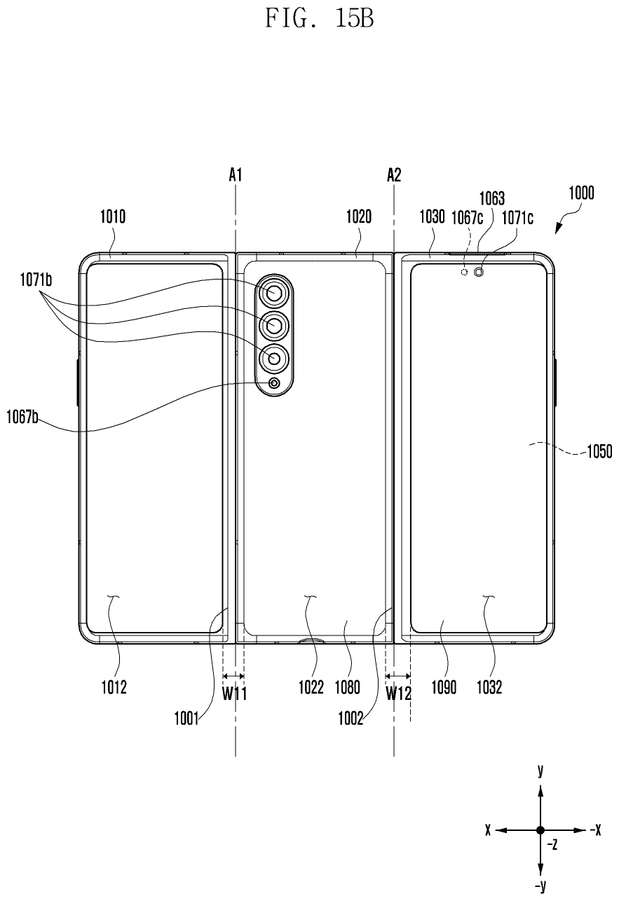

FIG. 15A is a schematic front view of a multi-foldable electronic device in an unfolded state according to an embodiment of the disclosure.

FIG. 15B is a schematic rear view of the multi-foldable electronic device in an unfolded state according to an embodiment of the disclosure.

The electronic device 1000 illustrated in FIGS. 15A, 15B, 16, and 17 may be a multi-foldable electronic device in which a plurality of housings 1010, 1020, and 1030 are configured to fold or unfold via hinge devices. The electronic device 1000 may include the flexible display 230 described with reference to FIGS. 6, 7A to 7C, 8A, 8B, 9A, 9B, 10A to 10C, 11A to 11C, and 12A to 12C. For example, the flexible display 1040 of the electronic device 1000 of FIGS. 13A, 13B, 14A, and 14B may include at least one of the first adhesive layer 510 of the flexible display described with reference to FIGS. 6, 7A to 7C, 8A, 8B, 9A, 9B, 10A to 10C, 11A to 11C, and 12A to 12C, the second adhesive layer 520 of FIGS. 7A to 7C, the second adhesive layer 520 of FIGS. 10A to 10C, the second adhesive layer 620 of FIGS. 11A to 11C, the third adhesive layer 630 of FIGS. 11A to 11C, and/or the second adhesive layer 720 described with reference to FIGS. 12A to 12C.

Referring to FIGS. 15A and 15B, the flexible display 1040 may include the flexible display 230 of FIGS. 6, 7A to 7C, 8A, 8B, 9A, 9B, 10A to 10C, 11A to 11C, and 12A to 12C described above. In an embodiment, the flexible display 1040 may include the window layer 410 of FIG. 6, a polarizer (POL) 420 (e.g., a polarizing film) disposed on the rear surface of the window layer 410, a display panel 430, a polymer layer 440, at least one functional layer 450, and a support plate 460.

At least two adhesive layers (e.g., the first adhesive layer 510) may be disposed between the first window layer 411 and the second window layer 412. The first window layer 411 and the second window layer 412 may be attached to each other through adhesive layers (e.g., the first adhesive layer 510 and the second adhesive layer 520). When the flexible display 1040 is viewed from above (e.g., in the z-direction of FIG. 15A), at least a portion of the first adhesive portion 511 of the first adhesive layer 510 may correspond to at least a portion of each of the first display area 1040a, the second display area 1040b, and the third display area 1040c of the flexible display 1040.

The second adhesive portion 512 of the first adhesive layer 510 may correspond to each of the first folding area 1040d and the second folding area 1040e of the flexible display 1040. The first folding area 1040d may be an area between the first display area 1040a and the second display area 1040b. The second folding area 1040e may be an area between the second display area 1040b and the third display area 1040c. The first folding area 1040d may be a portion that deforms (e.g., bends) during the folding or unfolding operation of the first housing 1010 and the second housing 1020 via the first hinge member 1001. The second folding area 1040e may be a portion that deforms (e.g., bends) during the folding or unfolding operation of the second housing 1020 and the second housing 1030 via the second hinge member 1002.

At least a portion of the second adhesive portion 512 may extend from the first folding area 1040d to the first display area 1040a and the second display area 1040b. For example, when viewed from above the flexible display 1040, the second adhesive portion 512 may be disposed in the first folding area 1040d and may at least partially extend into the first display area 1040a and the second display area 1040b. At least a portion of the second adhesive portion 512 may extend from the second folding area 1040e to the second display area 1040b and the third display area 1040c. For example, when viewed from above the flexible display 240, the second adhesive portion 512 may be disposed in the second folding area 1040e and may at least partially extend into the second display area 1040b and the third display area 1040c.

The first adhesive portion 511 may be made of a rigid material to provide a certain level of strength to the first display area 1040a, the second display area 1040b, and the third display area 1040c, which are substantially planar areas. The second adhesive portion 512 may be made of a relatively softer material than the first adhesive portion 511 to reduce the intensity of the reaction force generated in the folding areas 1040d and 1040e during the folding operation of the electronic device 1000.

An additional adhesive layer (e.g., the second adhesive layer 520 in FIGS. 7A to 7C, the second adhesive layer 520 in FIGS. 10A to 10C, the second adhesive layer 620 in FIGS. 11A to 11C, the third adhesive layer 630 in FIGS. 11A to 11C, and/or the second adhesive layer 720 in FIGS. 12A to 12C) may be disposed between the first window layer 411 and the second window layer 412, in addition to the first adhesive layer 510. The additional adhesive layer may enhance the durability of the flexible display 1040 or reduce the likelihood of failure of an adhesive member (e.g., the second adhesive portion 512) positioned in the folding areas 1040e and 1040e of the flexible display 1040.

The multi-foldable electronic device 1000 illustrated in FIGS. 15A and 15B may include the processor 120, the memory 130, the input module 150, the sound output module 155, the display module 160, the audio module 170, the sensor module 176, the interface 177, the connection terminal 178, the haptic module 179, the camera module 180, the antenna module 197, and/or the subscriber identification module 196, which are illustrated in FIG. 1.

Referring to FIGS. 15A and 15B, the multi-foldable electronic device 1000 according to various embodiments of the disclosure may include a first housing 1010, a second housing 1020, a third housing 1030, a first hinge member 1001, a second hinge member 1002, and/or a flexible display 1040.

The first housing 1010 may be foldably coupled to a first side of the second housing 1020 (e.g., in the x-axis direction). The first hinge member 1001 may be coupled between the first housing 1010 and the second housing 1020. The first hinge member 1001 may be disposed to allow the first housing 1010 and the second housing 1020 to be folded or unfolded relative to each other. The first hinge member 1001 may include a hinge device, a hinge module, a hinge plate, or a hinge assembly. The first housing 1010 and the second housing 1020 may be coupled to be rotatable about a first folding axis A1 using the first hinge member 1001.

The second housing 1020 may be foldably coupled to one side of the first housing 1010 (e.g., in the −x-axis direction). The second housing 1020 has a first side (e.g., in the x-axis direction) operatively coupled to at least a portion of the first housing 1010, and a second side (e.g., in the −x-axis direction) operatively coupled to at least a portion of the third housing 1030.

The third housing 1030 may be foldably coupled to the second side of the second housing 1020 (e.g., in the −x-axis direction). The second hinge member 1002 may be coupled between the second housing 1020 and the third housing 1030. The second hinge member 1002 may be disposed to allow the second housing 1020 and the third housing 1030 to be folded or unfolded relative to each other. The second hinge member 1002 may include a hinge device, a hinge module, a hinge plate, or a hinge assembly. The second housing 1020 and the third housing 1030 may be coupled to be rotatable about a second folding axis A2 using the second hinge member 1002. One side of the third housing 1030 (e.g., in the x-axis direction) may be foldably coupled to the second side of the second housing 1020 (e.g., in the −x-axis direction).

The multi-foldable electronic device 1000 may be configured such that the normal folding sequence involves the first housing 1010 being folded first relative to the second housing 1020 via the first hinge member 1001, followed by the third housing 1030 being folded relative to the second housing 1020 via the second hinge member 1002. The multi-foldable electronic device 1000 may be configured to recognize, as an abnormal folding sequence, a case in which the third housing 1030 folds first relative to the second housing 1020 via the second hinge member 1002, followed by the first housing 1010 being folded relative to the second housing 1020 via the first hinge member 1001.

The width w1 of the first housing 1010 in the horizontal direction (e.g., the x-axis direction and the −x-axis direction) may be configured to be smaller than the width w2 of the second housing 1020 in the horizontal direction (e.g., the x-axis direction and the −x-axis direction). The width w2 of the second housing 1020 in the horizontal direction (e.g., the x-axis direction and the −x-axis directions) may be configured to be substantially equal to the width w3 of the third housing 1030 in the horizontal direction (e.g., the x-axis and the −x-axis direction). The width w3 of the third housing 1030 in the horizontal direction (e.g., the x-axis direction and the −x-axis direction) may be configured to be greater than the width w2 of the second housing 1020 in the horizontal direction (e.g., the x-axis direction and the −x-axis direction).

The first housing 1010 and the second housing 1020 may be disposed on opposite sides of the first folding axis A1 on which the first hinge member 1001 is disposed, and may have an asymmetrical shape with respect to the first folding axis A1. The first housing 1010 and the second housing 1020 may have a symmetrical shape with respect to the first folding axis A1. The angle or distance between the first housing 1010 and the second housing 1020 may vary depending on whether the foldable electronic device 1000 is in the unfolded state, the folded state, or the intermediate state.

The second housing 1020 and the third housing 1030 may be disposed on opposite sides of the second folding axis A2 on which the second hinge member 1002 is disposed, and may have a substantially symmetrical shape with respect to the second folding axis A2. The second housing 1020 and the third housing 1030 may have an asymmetrical shape with respect to the second folding axis A2. The angle or distance between the second housing 1020 and the third housing 1030 may vary depending on whether the foldable electronic device 1000 is in the unfolded state, the folded state, or the intermediate state.

The width w12 of the second hinge member 1002 may be greater than the width w11 of the first hinge member 1001. For example, when the first housing 1010 is folded relative to the second housing 1020, and the third housing 1030 is folded relative to the second housing 1020, so that the third housing 1030 is disposed above the first housing 1010, the width w12 of the second hinge member 1002 may be greater than the width w11 of the first hinge member 1001. For example, the first hinge member 1001 may include a slim hinge with a narrow width. For example, the second hinge member 1002 may include a wide hinge that is wider than the first hinge member 1001.

Since the width w12 of the second hinge member 1002 is configured to be greater than the width w11 of the first hinge member 1001, a portion of the second housing 1020 may be brought into contact with a portion of the first housing 1010 when the third housing 1030 is folded first toward the second housing 1020. In this state, when the first housing 1010 is folded later toward the second housing 1020, the first housing 1010 may collide with a portion of the third housing 1030 and be damaged.

The flexible display 1040 may be disposed across at least a portion of the front surfaces of the first housing 1010, the second housing 1020, and the third housing 1030 (e.g., in the z-axis direction). The flexible display 1040 may be a first display, a foldable display, or a main display. A sub-display 1050 (e.g., a second display) may be disposed on the rear surface of the third housing 1030 (e.g., in the −z-axis direction).

Herein, the surface on which the flexible display 1040 is disposed may be defined as the front surface of the multi-foldable electronic device 1000 (e.g., in the z-axis direction), and the surface opposite to the front surface may be defined as the rear surface of the multi-foldable electronic device 1000 (e.g., in the −z-axis direction). The surface surrounding the space between the front surface and the rear surface may be defined as the side surface of the multi-foldable electronic device 1000.

The flexible display 1040 may include a first display area 1040a disposed on the first housing 1010, a second display area 1040b disposed on the second housing 1020, and a third display area 1040c disposed on the third housing 1030. The first display area 1040a, the second display area 1040b, and the third display area 1040c may be integrated to constitute the flexible display 1040. When the multi-foldable electronic device 1000 is in the unfolded state, the flexible display 1040 may be configured to be disposed on most of the front surface of the multi-foldable electronic device 200 (e.g., in the z-axis direction). At least a portion of the flexible display 1040 may be transformed into a flat or curved surface. The division of the flexible display 1040 into the first display area 1040a, the second display area 1040b, and the third display area 1040c may be an physical division. The flexible display 1040 may be fabricated as an overall seamless single screen.

When the multi-foldable electronic device 1000 is in the unfolded state, the first housing 1010 may include a first surface 1011 connected to at least a portion of the first hinge member 1001 and disposed to face the front of the multi-foldable electronic device 1000, a second surface 1012 oriented in the opposite direction of the first surface 1011, and/or a first side surface member 1013 surrounding at least a portion of the first space between the first surface 1011 and the second surface 1012.

When the multi-foldable electronic device 1000 is in the unfolded state, the second housing 1020 may include a third surface 1021 connected to at least a portion of the first hinge member 1001 and the second hinge member 1002 and disposed to face the front of the multi-foldable electronic device 1000, a fourth surface 1022 oriented in the opposite direction of the third surface 1021, and/or a second side surface member 1023 surrounding at least a portion of the second space between the third surface 1021 and the fourth surface 1022.

When the multi-foldable electronic device 1000 is in the unfolded state, the third housing 1030 may include a fifth surface 1031 connected to at least a portion of the second hinge member 1002 and disposed to face the front of the multi-foldable electronic device 1000, a sixth surface 1032 oriented in the opposite direction of the fifth surface 1031, and/or a third side surface member 1033 surrounding at least a portion of the third space between the fifth surface 1031 and the sixth surface 1032.

When the multi-foldable electronic device 1000 is in the unfolded state, the first surface 1011, the third surface 1021, and the fifth surface 1031 may be oriented in substantially the same direction (e.g., the z-axis direction). When the multi-foldable electronic device 1000 is in the unfolded state, the second surface 1012, the fourth surface 1022, and the sixth surface 1032 may be oriented in substantially the same direction (e.g., the −z-axis direction).

When the first housing 1010 and the second housing 1020 of the multi-foldable electronic device 1000 are in the folded state, the first surface 1011 and the third surface 1021 may be disposed to face each other. When the second housing 1020 and the third housing 1030 of the multi-foldable electronic device 1000 are in the folded state, the third surface 1021 and the fifth surface 1031 may be disposed to face each other.

The multi-foldable electronic device 1000 may include a recess 1045 provided to accommodate the flexible display 1040 through structural coupling of the first housing 1010, the second housing 1020, and the third housing 1030. The recess 1045 may have substantially the same size as the flexible display 1040.

When the multi-foldable electronic device 1000 is in the unfolded state, the first housing 1010, the second housing 1020, and the third housing 1030 may form an angle of about 180 degrees, and the first display area 1040a, the second display area 1040b, and the third display area 1040c of the flexible display 1040 may be disposed to be oriented in substantially the same direction (e.g., the z-axis direction) while forming substantially the same plane.

The first housing 1010 and the second housing 1020 may form an angle that allows the first and second housings to be stopped at a predetermined folding angle between the folded state and the unfolded state using the first hinge member 1001 (e.g., free-stop function). The first housing 1010 may be rotated to the rear surface of the second housing 1020 using the first hinge member 1001 while being pressed in the unfolding direction (e.g., the −z-axis direction) with reference to a predetermined inflection angle.

The second housing 1020 and the third housing 1030 may form an angle that allows the second and third housings to be stopped at a predetermined folding angle between the folded state and the unfolded state using the second hinge member 1002. The third housing 1030 may be rotated to the rear surface of the second housing 1020 using the second hinge member 1002 while being pressed in the unfolding direction (e.g., the −z-axis direction) with reference to a predetermined inflection angle.

The flexible display 1040 may be disposed to be supported by the first surface 1011 of the first housing 1010, the first hinge member 1001, the third surface 1021 of the second housing 1020, the second hinge member 1002, and the fifth surface 1031 of the third housing 1030. The sub-display 1050 may be disposed in the inner space of the third housing 1030 to be at least partially visible from the outside through the sixth surface 1032. In various embodiments, the sub-display 1050 may be disposed in the inner space of the first housing 1010 to be visible from the outside through the second surface 1012.

The flexible display 1040 may be mainly used when the multi-foldable electronic device 1000 is in the unfolded state, and the sub-display 1050 may be mainly used when the foldable electronic device 1000 is in the folded state. The flexible display 240 may be disposed in an accommodation space defined by the first housing 1010, the second housing 1020, and the third housing 1030. For example, the flexible display 1040 may be disposed in the recess 1045 defined by the first housing 1010, the second housing 1020, and the third housing 1030.

According to an embodiment, the multi-foldable electronic device 1000 may include a first rear surface cover 1080 disposed on the fourth surface 1022 of the second housing 1020 and a second rear surface cover 1090 disposed on the sixth surface 1032 of the third housing 1030. At least a portion of the first rear surface cover 1080 may be integrated with a portion of the second side surface member 1023. At least a portion of the second rear surface cover 1090 may be integrated with a portion of the third side surface member 1033. At least one of the first rear surface cover 1080 and the second rear surface cover 1090 may be made of a substantially transparent plate (e.g., a glass plate including various coating layers, or a polymer plate) or an opaque plate.

The first rear surface cover 1080 may be made of, for example, coated or colored glass, ceramic, polymer, metal (e.g., aluminum, stainless steel (STS), or magnesium), or an opaque plate such as a combination of two or more of these materials. The second rear surface cover 1090 may be made of a substantially transparent plate of, for example, glass or polymer. In this case, the sub-display 1050 may be disposed in the inner space of the third housing 1030 to be visible from the outside through the second rear surface cover 1090.

The multi-foldable electronic device 1000 may include at least one of an input module 1061, sound output modules 1063 and 1065, sensor modules 1067a, 1067b, and 1067c, camera modules 1071a, 1071b, and 1071c, key input devices 1073, an indicator (not illustrated), or a connector port 1075. At least one of the above-mentioned components may be omitted from the multi-foldable electronic device 1000, or at least one other component may be additionally included in the multi-foldable electronic device 1000.

According to an embodiment, the input module 1061 may include at least one microphone disposed to detect the direction of sound. The input module 1061 may include the input module 150 illustrated in FIG. 1.

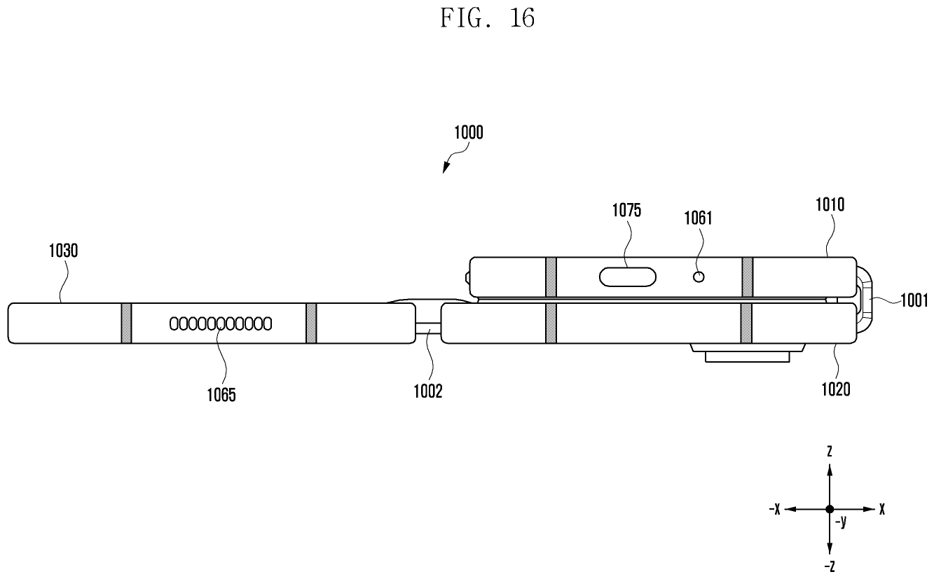

FIG. 16 is a view schematically illustrating a multi-foldable electronic device in a state in which a first housing is folded relative to a second housing according to an embodiment of the disclosure.

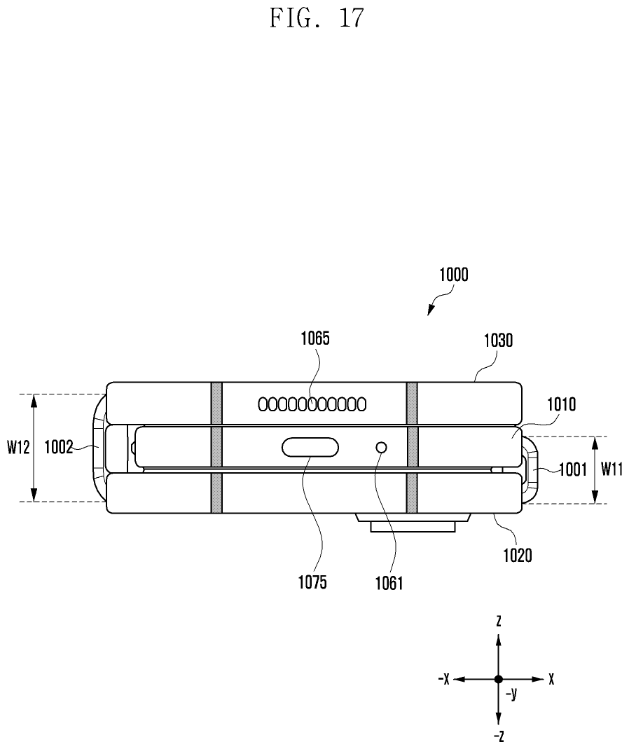

FIG. 17 is a view schematically illustrating the multi-foldable electronic device in a state in which the first housing and a third housing are folded relative to the second housing according to an embodiment of the disclosure.

FIG. 16 is a view of the multi-foldable electronic device 1000 viewed in the −y-axis direction in the state in which the first housing 1010 is folded toward the second housing 1020. FIG. 17 is a view of the multi-foldable electronic device 1000 viewed in the −y-axis direction in the state in which the first housing 1010 is folded first toward the second housing 1020 and the third housing 1030 is subsequently folded toward the second housing 1020 (e.g., a normal folding sequence).

Referring to FIGS. 16 and 17, the multi-foldable electronic device 1000 may include the first housing 1010, the second housing 1020, the third housing 1030, a first hinge member 1001, and a second hinge member 1002.

The first housing 1010 may be folded first onto the second housing 1020 (e.g., the z-axis direction) via the first hinge member 1001 (e.g., a slim hinge).

After the first housing 1010 is folded relative to the second housing 1020 via the first hinge member 1001, the third housing 1030 may be folded toward the second housing 1020 via the second hinge member 1002 (e.g., a wide hinge) to be disposed on the first housing 1010 (e.g., the z-axis direction).

The multi-foldable electronic device 1000 may recognize, as a normal folding sequence, a case where the first housing 1010 is first folded toward the second housing 1020 via the first hinge member 1001, and the third housing 1030 is subsequently folded toward the second housing 1020 via the second hinge member 1002. The multi-foldable electronic device 1000 may recognize, as an abnormal folding sequence, a case where the third housing 1030 is first folded toward the second housing 1020 via the second hinge member 1002, and the first housing 1010 is subsequently folded toward the second housing 1020 via the first hinge member 1001.

The first hinge member 1001 may have a first width w11. The second hinge member 1002 may have a second width w12. The second width w12 may be greater than the first width w11. Since the first housing 1010 should be folded relative to the second housing 1020, and the third housing 1030 should be folded relative to the second housing 1020 to be disposed on the first housing 1010 (e.g., the z-axis direction), the second width w12 of the second hinge member 1002 may be configured to be greater than the first width w11 of the first hinge member 1001. For example, the first hinge member 1001 may include a slim hinge with a narrow width. For example, the second hinge member 1002 may include a wide hinge that is wider than the first hinge member 1001.

Since the second width w12 of the second hinge member 1002 is configured to be greater than the first width w11 of the first hinge member 1001, a portion of the second housing 1020 may be brought into contact with a portion of the first housing 1010 when the third housing 1030 is folded first toward the second housing 220. In this state, when the first housing 1010 is folded later toward the second housing 1020, the first housing 1010 may collide with a portion of the third housing 1030 and be damaged.

The risk of failure of the multi-foldable electronic device 1000 may be reduced when the first housing 1010 is folded first toward the second housing 1020, and the third housing 1030 is subsequently folded toward the second housing 1020 (e.g., normal folding sequence).

When the third housing 1030 is folded first toward the second housing 1020 and the first housing 1010 is subsequently folded toward the second housing 1020 (e.g., abnormal folding order), the multi-foldable electronic device 1000 may provide at least one notification (e.g., warning sound, vibration, and/or pop-up message) to a user.

The above-described multi-foldable electronic device 1000 has been described on the premise that the first housing 1010 is folded toward the second housing 1020 in an in-folding manner, and the third housing 1030 is folded toward the second housing 1020 in an in-folding manner. However, the disclosure is not limited thereto. For example, the multi-foldable electronic device 1000 may be configured such that the first housing 1010 is folded relative to the second housing 1020 in an out-folding manner, causing a portion (e.g., the folding area 1040d) of the flexible display 1040 disposed on the first housing 1010 and the second housing 1020 to bend at an angle of 180 degrees or more, thereby exposing the first display area 1040a of the flexible display 1040 disposed on the first housing 1010 to the outside. In this case, the third housing 1030 may be folded toward the second housing 1020 in the in-folding manner, such that the second display area 1040b and the third display area 1040c face each other and are not exposed to the outside of the electronic device 1000. Conversely, the third housing 1030 may be folded relative to the second housing 1020 in the out-folding manner, causing a portion (e.g., the folding area 1040e) of the flexible display 1040 disposed on the second housing 1020 and the third housing 1030 to bend at an angle of 180 degrees or more, thereby exposing the third display area 1040c of the flexible display 1040 disposed on the third housing 1030 to the outside. In this case, the first housing 1010 may be folded toward the second housing 1020 in the in-folding manner, such that the first display area 1040a and the second display area 1040b face each other and are not exposed to the outside of the electronic device 1000.

According to an embodiment of the disclosure, an electronic device 101 or 200 may include a first housing 210, a second housing 220 configured to move relative to the first housing, and a flexible display 230 including a first portion 230a and a second portion 230b, at least a portion of the second portion being configured to be at least partially slid into or slid out from an internal space 2101 of the electronic device based on movement of the second housing relative to the first housing. The flexible display may include a first window layer 411, a second window layer 412 disposed on the first window layer, and at least two adhesive layers including a first adhesive layer 510 and a second adhesive layer 520. The first and second adhesive layers may be disposed between the first window layer and the second window layer to bond the first window layer to the second window layer. The first adhesive layer 510 may include a first adhesive portion 511 corresponding to the first portion of the flexible display and a second adhesive portion 512 corresponding to the second portion of the flexible display. The second adhesive portion may have a modulus lower than a modulus of the first adhesive portion, and the modulus of the second adhesive layer may be equal to or lower than the modulus of the first adhesive portion.

In an embodiment, the modulus of the second adhesive layer may be equal to, higher than, or lower than the modulus of the second adhesive portion.

In an embodiment, the second adhesive layer may be disposed between the first window layer and the first adhesive layer or between the second window layer and the first adhesive layer.

In an embodiment, the second adhesive layer may be disposed on a first surface of the first adhesive layer, and the at least two adhesive layers may include a third adhesive layer 630 disposed on a second surface opposite to the first surface of the first adhesive layer.

In an embodiment, the modulus of the third adhesive layer may be equal to or lower than the modulus of the first adhesive portion.

In an embodiment, the modulus of the third adhesive layer may be equal to, higher than, or lower than the modulus of the second adhesive portion.

In an embodiment, the second adhesive layer may be disposed between the first surface of the first adhesive layer and the second window layer, and the third adhesive layer may be disposed between the second surface of the first adhesive layer and the first window layer.

In an embodiment, the second adhesive layer may include a third adhesive portion 721 corresponding to the first adhesive portion and a fourth adhesive portion 722 corresponding to the second adhesive portion, and the modulus of the fourth adhesive portion may be lower than the modulus of the third adhesive portion.

In an embodiment, the first window layer may be a glass layer disposed on a display panel of the flexible display.

In an embodiment, the second window layer may include at least one of polyethylene terephthalate (PET), thermoplastic polyurethane (TPU), polyurethane (PU), and polyimide (PI).

In an embodiment, the first adhesive layer and the second adhesive layer may include at least one of a non-Newtonian fluid, a pressure-sensitive adhesive (PSA), an optically clear adhesive (OCA), an optically clear resin (OCR), a heat-reactive adhesive, a general adhesive, and a double-sided tape.

In an embodiment, the modulus of the first adhesive portion may range from 0.1 MPa to 0.6 Mpa.

In an embodiment, the modulus of the second adhesive portion may range from 0.01 MPa to 0.04 Mpa.

According to an embodiment of the disclosure, a flexible display 230 may be disposed in an electronic device 101 or 200, in which a first housing 210 and a second housing 220 are movably coupled, and may have a first portion 230a and a second portion 230b configured to be at least partially slid into an inner space 2101 of the electronic device or slid out from the inner space based on movement of the second housing relative to the first housing. The flexible display 230 may include a first window layer 411, a second window layer 412 disposed on the first window layer, and at least two adhesive layers including a first adhesive layer 510 and a second adhesive layer 520. The at least two adhesive layer may be disposed between the first window layer and the second window layer to bond the first window layer to the second window layer. The first adhesive layer may include a first adhesive portion 511 corresponding to the first portion of the flexible display and a second adhesive portion 512 corresponding to the second portion of the flexible display. The second adhesive portion may have a modulus lower than a modulus of the first adhesive portion, and the modulus of the second adhesive layer may be equal to or lower than the modulus of the first adhesive portion.

In an embodiment, the modulus of the second adhesive layer may be equal to, higher than, or lower than the modulus of the second adhesive portion.

In an embodiment, the second adhesive layer may be disposed between the first window layer and the first adhesive layer or between the second window layer and the first adhesive layer.

In an embodiment, the second adhesive layer may be disposed on a first surface of the first adhesive layer, and the at least two adhesive layers may include a third adhesive layer 630 disposed on a second surface opposite to the first surface of the first adhesive layer.

In an embodiment, the modulus of the third adhesive layer may be equal to or lower than the modulus of the first adhesive portion.

In an embodiment, the modulus of the third adhesive layer may be equal to, higher than, or lower than the modulus of the second adhesive portion.

In an embodiment, the first window layer may be a glass layer disposed on a display panel of the flexible display, and the second window layer may include at least one of polyethylene terephthalate (PET), thermoplastic polyurethane (TPU), polyurethane (PU), and polyimide (PI).

It should be appreciated that various embodiments of the disclosure and the terms used therein are not intended to limit the technological features set forth herein to particular embodiments and the disclosure includes various changes, equivalents, or alternatives for a corresponding embodiment. With regard to the description of the drawings, similar reference numerals may be used to designate similar or relevant elements. A singular form of a noun corresponding to an item may include one or more of the items, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one or all possible combinations of the items enumerated together in a corresponding one of the phrases. Such terms as “a first,” “a second,” “the first,” and “the second” may be used to simply distinguish a corresponding element from another, and does not limit the elements in other aspect (e.g., importance or order). If an element (e.g., a first element) is referred to, with or without the term “operatively” or “communicatively”, as “coupled with/to” or “connected with/to” another element (e.g., a second element), it means that the element may be coupled/connected with/to the other element directly (e.g., wiredly), wirelessly, or via a third element.

According to various embodiments, each element (e.g., a module or a program) of the above-described elements may include a single entity or multiple entities, and some of the multiple entities may be separately disposed in any other element. According to various embodiments, one or more of the above-described elements or operations may be omitted, or one or more other elements or operations may be added. Alternatively or additionally, a plurality of elements (e.g., modules or programs) may be integrated into a single element. In such a case, according to various embodiments, the integrated element may still perform one or more functions of each of the plurality of elements in the same or similar manner as they are performed by a corresponding one of the plurality of elements before the integration. According to various embodiments, operations performed by the module, the program, or another element may be carried out sequentially, in parallel, repeatedly, or heuristically, or one or more of the operations may be executed in a different order or omitted, or one or more other operations may be added.

It will be appreciated that, in addition to the above-described embodiments, the disclosure also considers and includes embodiments based on combinations of any two or more of the embodiments set forth above and embodiments including any combinations of the above features. They are disclosed herein. That is, although there is no explicit mention that two features may be combined or two embodiments may be combined, it does not mean that these combinations are not contemplated, but the combinations should be construed to be included herein.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a first housing;
a second housing configured to move with respect to the first housing; and
a flexible display including a first display portion and a second display portion, wherein at least part of the second display portion is drawn into or withdrawn from an internal space of the electronic device in accordance with the second housing moving with respect to the first housing,
wherein the flexible display comprises:
a first window layer,
a second window layer, and
at least two adhesive layers, including a first adhesive layer and a second adhesive layer, disposed between the first window layer and the second window layer, the at least two adhesive layers configured to adhesively attach the first window layer to the second window layer,
wherein the first adhesive layer comprises a first adhesive portion corresponding to the first display portion and a second adhesive portion corresponding to the second display portion, and
wherein a modulus of the second adhesive portion is lower than a modulus of the first adhesive portion and a modulus of the second adhesive layer is equal to or lower than the modulus of the first adhesive portion.

2. The electronic device according to claim 1, wherein the modulus of the second adhesive layer is different than the modulus of the second adhesive portion.

3. The electronic device according to claim 1, wherein the second adhesive layer is disposed between the first window layer and the first adhesive layer or between the second window layer and the first adhesive layer.

4. The electronic device according to claim 1,
wherein the second adhesive layer disposed on a first surface of the first adhesive layer, and
wherein the at least two adhesive layers comprises a third adhesive layer disposed on a second surface, opposite to the first surface, of the first adhesive layer.

5. The electronic device according to claim 4, wherein the modulus of the third adhesive layer is equal to or lower than the modulus of the first adhesive portion.

6. The electronic device according to claim 4, wherein the modulus of the third adhesive layer is equal to, greater than, or lower than the modulus of the second adhesive portion.

7. The electronic device according to claim 4,
wherein the second adhesive layer is disposed between the first surface of the first adhesive layer and the second window layer, and
wherein the third adhesive layer is disposed between the second surface of the first adhesive layer and the first window layer.

8. The electronic device according to claim 1, wherein the second adhesive layer comprises:
a third adhesive portion corresponding to the first adhesive portion; and
a fourth adhesive portion corresponding to the second adhesive portion, wherein a modulus of the fourth adhesive portion is lower than a modulus of the third adhesive portion.

9. The electronic device according to claim 1, wherein the first window layer is a glass layer disposed on a display panel of the flexible display.

10. The electronic device according to claim 1, wherein the second window layer comprises at least one of polyethylene terephthalate (PET), thermoplastic polyurethane (TPU), polyurethane (PU), and polyimide (PI).

11. The electronic device according to claim 1, wherein the first adhesive layer and the second adhesive layer comprise at least one of pressure-sensitive adhesive (PSA), optically clear adhesive (OCA), optically clear resin (OCR), non-Newtonian fluid, a heat-reactive adhesive, an adhesive, and a double-sided tape.

12. The electronic device according to claim 1, wherein the modulus of the first adhesive portion is from 0.1 MPa to 0.6 MPa.

13. The electronic device according to claim 1, wherein the modulus of the second adhesive portion is from 0.01 MPa to 0.04 MPa.

14. A flexible display disposed in an electronic device, in which a first housing and a second housing are movably coupled, and having a first portion and a second portion configured to be at least partially slid into an inner space of the electronic device or slid out from the inner space based on movement of the second housing relative to the first housing, the flexible display comprising:
a first window layer;
a second window layer disposed on the first window layer; and
at least two adhesive layers including a first adhesive layer and a second adhesive layer, the first adhesive layer being disposed between the first window layer and the second window layer to bond the first window layer to the second window layer,
wherein the first adhesive layer comprises a first adhesive portion corresponding to the first portion of the flexible display and a second adhesive portion corresponding to the second portion of the flexible display,
wherein the second adhesive portion has a modulus lower than a modulus of the first adhesive portion, and
wherein the second adhesive layer has a modulus equal to or lower than the modulus of the first adhesive portion.

15. The flexible display of claim 14, wherein the modulus of the second adhesive layer is different than the modulus of the second adhesive portion.

16. The flexible display of claim 14, wherein the second adhesive layer is disposed between the first window layer and the first adhesive layer or between the second window layer and the first adhesive layer.

17. The flexible display of claim 14,
wherein the second adhesive layer is disposed on a first surface of the first adhesive layer, and
wherein the at least two adhesive layers comprises a third adhesive layer disposed on a second surface opposite to the first surface of the first adhesive layer.

18. The flexible display of claim 17, wherein the third adhesive layer has a modulus equal to or lower than the modulus of the first adhesive portion.

19. The flexible display of claim 17, wherein the modulus of the third adhesive layer is different than the modulus of the second adhesive portion.

20. The flexible display of claim 14,
wherein the first window layer is a glass layer disposed on a display panel of the flexible display, and
wherein the second window layer comprises at least one of polyethylene terephthalate (PET), thermoplastic polyurethane (TPU), polyurethane (PU), and polyimide (PI).

21. The flexible display of claim 14, wherein the modulus of the first adhesive portion is greater than or equal to 0.6 MPa.

22. The flexible display of claim 14, wherein the second window layer has a thickness of 65 micrometers or less.
